(19) United States
(12) Patent Application Publication
(10) Pub. No.: US 2024/0213026 A1
(43) Pub. Date: Jun. 27, 2024

(54) CHEMICAL MECHANICAL POLISHING OF METAL GATE CUTS FORMED AFTER SOURCE AND DRAIN CONTACTS

(71) Applicant: Intel Corporation, Santa Clara, CA (US)

(72) Inventors: Matthew J. Prince, Portland, OR (US); Lawrence Zaino, Beaverton, OR (US); Barry B. Butler, Hillsboro, OR (US); Girish Sharma, Hillsboro, OR (US); Robert R. Mitchell, Portland, OR (US); Rajaram A. Pai, Lake Oswego, OR (US); Niels Sveum, Portland, OR (US); Alison V. Davis, Portland, OR (US); Chun Chen Kuo, Portland, OR (US); Reza Bayati, Portland, OR (US); Swapnadip Ghosh, Hillsboro, OR (US)

(73) Assignee: Intel Corporation, Santa Clara, CA (US)

(21) Appl. No.: 18/085,768

(22) Filed: Dec. 21, 2022

(51) Int. Cl. H01L 21/28; B24B 37/04; H01L 21/8238; H01L 27/092; H01L 29/06; H01L 29/417; H01L 29/423; H01L 29/66; H01L 29/775

(52) U.S. Cl. CPC H01L 21/28123; B24B 37/04; H01L 21/823807; H01L 21/823814; H01L 21/823828; H01L 21/823871; H01L 21/823878; H01L 27/092; H01L 29/0673; H01L 29/41733; H01L 29/42392; H01L 29/66439; H01L 29/775

(57) ABSTRACT

Techniques are provided herein to form semiconductor devices that include a gate cut formed after the formation of source or drain contacts and with a top surface that is substantially coplanar with a top surface of the source or drain contacts. An example semiconductor device includes a gate structure around or otherwise on a semiconductor region and a dielectric layer present on a top surface of the gate structure. Conductive contacts are formed over source and drain regions along a source/drain contact recess or trench. The gate structure may be interrupted with a gate cut that extends through an entire thickness of the gate structure and includes a dielectric material. A top surface of the gate cut may be polished until it is substantially coplanar with a top surface of the dielectric layer over the gate structure and a top surface of the source or drain contacts.

### FIELD OF THE DISCLOSURE

The present disclosure relates to integrated circuits, and more particularly, to metal gate cuts made in semiconductor devices.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures used to isolate adjacent transistors becomes challenging. Accordingly, there remain a number of non-trivial challenges with respect to forming semiconductor devices.

### BRIEF DESCRIPTION OF THE DRAWINGS

FIGS. 1A and 1B are cross-sectional views of some semiconductor devices that illustrate a gate cut between devices having a top surface coplanar with a top surface of source or drain contacts, in accordance with an embodiment of the present disclosure.

FIG. 1C is a plan view of the integrated circuit showing the gate cut of FIGS. 1A and 1B formed between two semiconductor devices, in accordance with an embodiment of the present disclosure.

FIGS. 1D and 1E are cross-sectional views of a gate cut that abuts a source or drain region and a contact over the source or drain region, in accordance with an embodiment of the present disclosure.

FIGS. 2A and 2B are cross-sectional views that illustrate a stage in a first example process for forming semiconductor devices that have a gate cut with a top surface coplanar with a top surface of source or drain contacts, in accordance with some embodiments of the present disclosure.

FIGS. 3A and 3B are cross-sectional views that illustrate another stage in the first example process for forming semiconductor devices that have a gate cut with a top surface coplanar with a top surface of source or drain contacts, in accordance with some embodiments of the present disclosure.

FIGS. 4A and 4B are cross-sectional views that illustrate another stage in the first example process for forming semiconductor devices that have a gate cut with a top surface coplanar with a top surface of source or drain contacts, in accordance with some embodiments of the present disclosure.

FIGS. 5A and 5B are cross-sectional views that illustrate another stage in the first example process for forming semiconductor devices that have a gate cut with a top surface coplanar with a top surface of source or drain contacts, in accordance with some embodiments of the present disclosure.

FIGS. 6A and 6B are cross-sectional views that illustrate another stage in the first example process for forming semiconductor devices that have a gate cut with a top surface coplanar with a top surface of source or drain contacts, in accordance with some embodiments of the present disclosure.

FIGS. 7A and 7B are cross-sectional views that illustrate another stage in the first example process for forming semiconductor devices that have a gate cut with a top surface coplanar with a top surface of source or drain contacts, in accordance with some embodiments of the present disclosure.

FIGS. 8A and 8B are cross-sectional views that illustrate another stage in the first example process for forming semiconductor devices that have a gate cut with a top surface coplanar with a top surface of source or drain contacts, in accordance with some embodiments of the present disclosure.

FIGS. 9A and 9B are cross-sectional views that illustrate another stage in the first example process for forming semiconductor devices that have a gate cut with a top surface coplanar with a top surface of source or drain contacts, in accordance with some embodiments of the present disclosure.

FIGS. 10A and 10B are cross-sectional views that illustrate another stage in the first example process for forming semiconductor devices that have a gate cut with a top surface coplanar with a top surface of source or drain contacts, in accordance with some embodiments of the present disclosure.

FIGS. 11A and 11B are cross-sectional views that illustrate a stage in a second example process for forming semiconductor devices that have a gate cut with a top surface coplanar with a top surface of source or drain contacts, in accordance with some embodiments of the present disclosure.

FIGS. 12A and 12B are cross-sectional views that illustrate another stage in the second example process for forming semiconductor devices that have a gate cut with a top surface coplanar with a top surface of source or drain contacts, in accordance with some embodiments of the present disclosure.

FIGS. 13A and 13B are cross-sectional views that illustrate another stage in the second example process for forming semiconductor devices that have a gate cut with a top surface coplanar with a top surface of source or drain contacts, in accordance with some embodiments of the present disclosure.

FIGS. 14A and 14B are cross-sectional views that illustrate another stage in the second example process for forming semiconductor devices that have a gate cut with a top surface coplanar with a top surface of source or drain contacts, in accordance with some embodiments of the present disclosure.

FIGS. 15A and 15B are cross-sectional views that illustrate a stage in a third example process for forming semiconductor devices that have a gate cut with a top surface coplanar with a top surface of source or drain contacts, in accordance with some embodiments of the present disclosure.

FIGS. 16A and 16B are cross-sectional views that illustrate another stage in the third example process for forming semiconductor devices that have a gate cut with a top surface coplanar with a top surface of source or drain contacts, in accordance with some embodiments of the present disclosure.

FIG. 17 illustrates a cross-sectional view of a chip package containing one or more semiconductor dies, in accordance with some embodiments of the present disclosure.

FIG. 18 is a flowchart of a fabrication process for semiconductor devices having a gate cut with a top surface coplanar with a top surface of source or drain contacts, in accordance with an embodiment of the present disclosure.

FIG. 19 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include a gate cut formed after the formation of source or drain contacts and with a top surface that is substantially coplanar with a top surface of the source and/or drain contacts (more generally, diffusion contacts). The techniques can be used in any number of integrated circuit applications and are particularly useful with respect to device layer transistors, such as finFETs or gate-all-around transistors (e.g., ribbonFETs and nanowire FETs). In an example, a semiconductor device includes a gate structure around or otherwise on a semiconductor region (or channel region). The semiconductor region can be, for example, a fin of semiconductor material that extends from a source region to a drain region, or one or more nanowires or nanoribbons or nanosheets of semiconductor material that extend from a source region to a drain region (more generally, diffusion regions). A dielectric layer may be present on a top surface of the gate structure. Conductive contacts are formed over the source and drain regions along a source/drain contact recess or trench. The contacts may extend within the source and drain regions, and/or along sides of the source and drain regions, and/or wrap around the source and drain regions. The gate structure may be interrupted, for example, between two transistors with a gate cut that extends through an entire thickness of the gate structure and includes a dielectric material to electrically isolate the portions of the gate structure on either side of the gate cut. The gate cut may further extend past the gate structure and into the diffusion contact trench region. A dielectric material used to form the gate cut may be deposited into a gate cut recess and polished back using chemical mechanical polishing (CMP) until a top surface of the diffusion contacts is exposed. Accordingly, a top surface of the gate cut is polished until it is substantially coplanar with a top surface of the dielectric layer over the gate structure and a top surface of the diffusion contacts.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Example structures like gate cuts are used in integrated circuit design to isolate gate structures from one another. One possible way to form gate cuts is to use a gate patterning scheme that uses the poly-cut flow, where the gate cut is formed prior to formation of the final metal gate. Another approach might be to use a gate patterning scheme that uses the metal gate cut flow. Such approaches generally etch a trench or other recess through a thickness of the poly (dummy) or metal gate structure and fill the trench with a dielectric material. Controlling the height of the metal gate cut can be challenging.

Thus, and in accordance with an embodiment of the present disclosure, gate cut forming techniques are provided herein that include forming source and drain contacts within the source or drain contact trench prior to formation of any gate cuts, and polishing back a dielectric material used to form the gate cuts until a top surface of the gate cut is substantially coplanar with a top surface of the source or drain contacts. In this way, the presence of the source or drain contacts is leveraged to control the final height of the gate cut by stopping the polishing process when the source or drain contacts are exposed. A CMP process may be used to perform the polishing. As used herein, two surfaces are considered to be substantially coplanar if they are polished together using the same CMP process. In another example, the height variation between two surfaces that are substantially coplanar may be less than 1 nm.

In an example, conductive source or drain contacts are formed on corresponding source or drain regions prior to any gate cuts being formed. A gate cut recess may be formed through a dielectric layer over a gate structure and through an entire thickness of the underlying gate structure. The gate cut recess may be filled or at least partially filled with a dielectric material, such as silicon nitride or silicon dioxide or other dielectric suitable for a gate cut. One or more polishing steps using CMP may then be used to polish back the dielectric material until a top surface of the source or drain contacts is exposed. By using the conductive top surfaces of the source or drain regions to stop the CMP process, a top surface of the dielectric gate cut is substantially coplanar with both a top surface of the dielectric layer over the gate structure and with the top surfaces of the source or drain contacts. There are multiple ways to utilize the CMP steps based on the materials used, as is described below.

According to an embodiment, an integrated circuit includes a semiconductor device having a semiconductor region extending in a first direction between a source region and a drain region, and a gate structure extending in a second direction over the semiconductor region. The integrated circuit further includes a dielectric layer on a top surface of the gate structure, a first conductive contact on the source region and a second conductive contact on the drain region, and a gate cut extending in a third direction through an entire thickness of the gate structure. The gate cut includes a dielectric material, and a top surface of the gate cut is substantially coplanar with both a top surface of the dielectric layer and top surfaces of the first and second conductive contacts.

According to another embodiment, an integrated circuit includes a semiconductor region extending in a first direction between a first source or drain region and a second source or drain region, a gate structure extending in a second direction over the semiconductor region, a dielectric layer on a top surface of the gate structure, a first conductive contact on the first source or drain region and a second conductive contact on the second source or drain region, and a gate cut extending in a third direction through an entire thickness of the gate structure and extending in the first direction such that the gate cut contacts at least a portion of the first source or drain region and at least a portion of the first conductive contact. The gate cut includes a dielectric material and has a top surface that is substantially coplanar with a top surface of the dielectric layer and a top surface of the first conductive contact.

According to another embodiment, a method of forming an integrated circuit includes forming a fin comprising semiconductor material, the fin extending above a substrate and extending in a first direction; forming a source region and a drain region at opposite ends of the semiconductor material; forming a gate structure extending over the semiconductor material in a second direction different from the first direction; forming a dielectric layer on a top surface of the gate structure; forming a first conductive contact on the source region, and a second conductive contact on the drain region; forming a dielectric mask layer over the dielectric layer and over the first conductive contact and second conductive contact; forming a recess through the dielectric mask layer and through an entire thickness of the underlying gate structure; depositing a dielectric material within the recess and over at least a top surface of the dielectric mask layer; and recessing the dielectric material using chemical mechanical polishing (CMP), until a top surface of the dielectric material is coplanar with both a top surface of the dielectric layer and the first and second conductive contacts.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a gate cut extending through an entire thickness of a gate structure and having a top surface that is substantially coplanar with a top surface of conductive diffusion contacts and/or a top surface of a dielectric layer over the gate structure. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

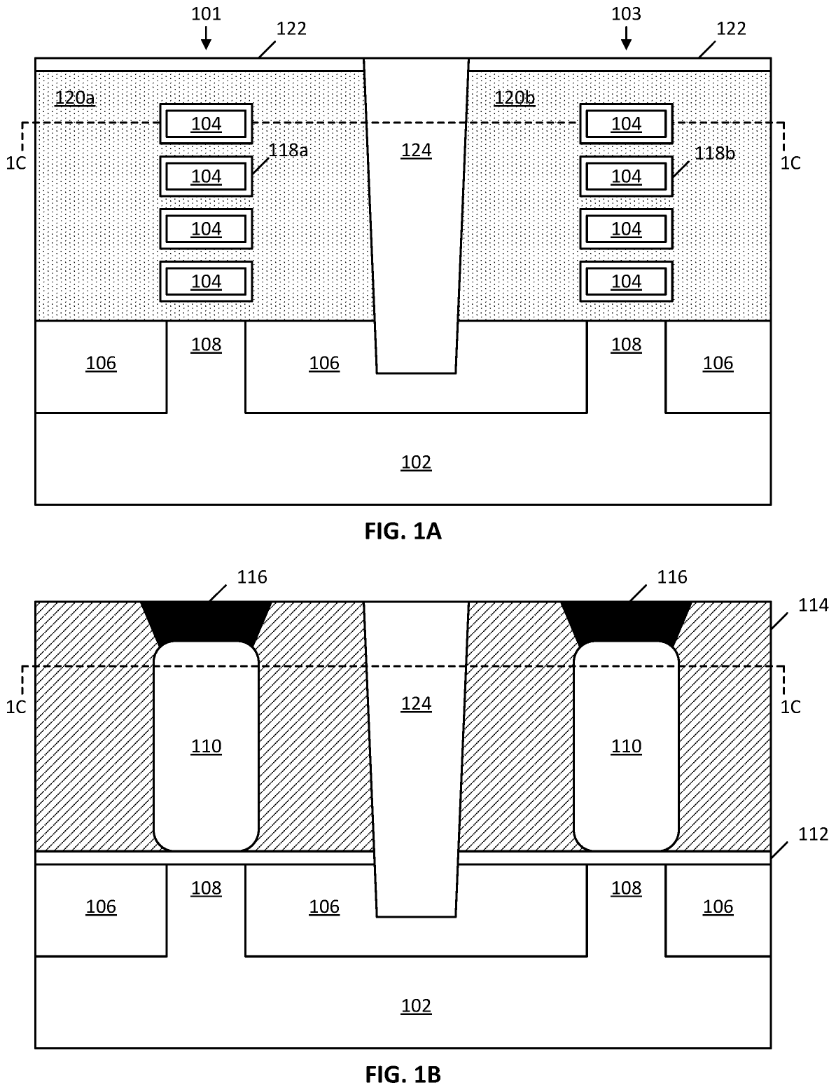

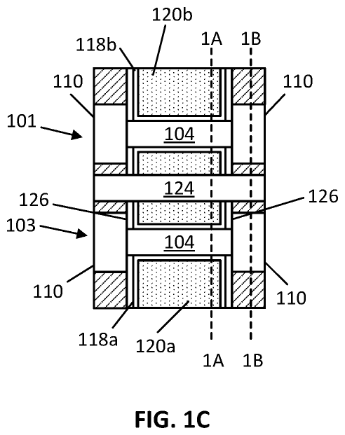

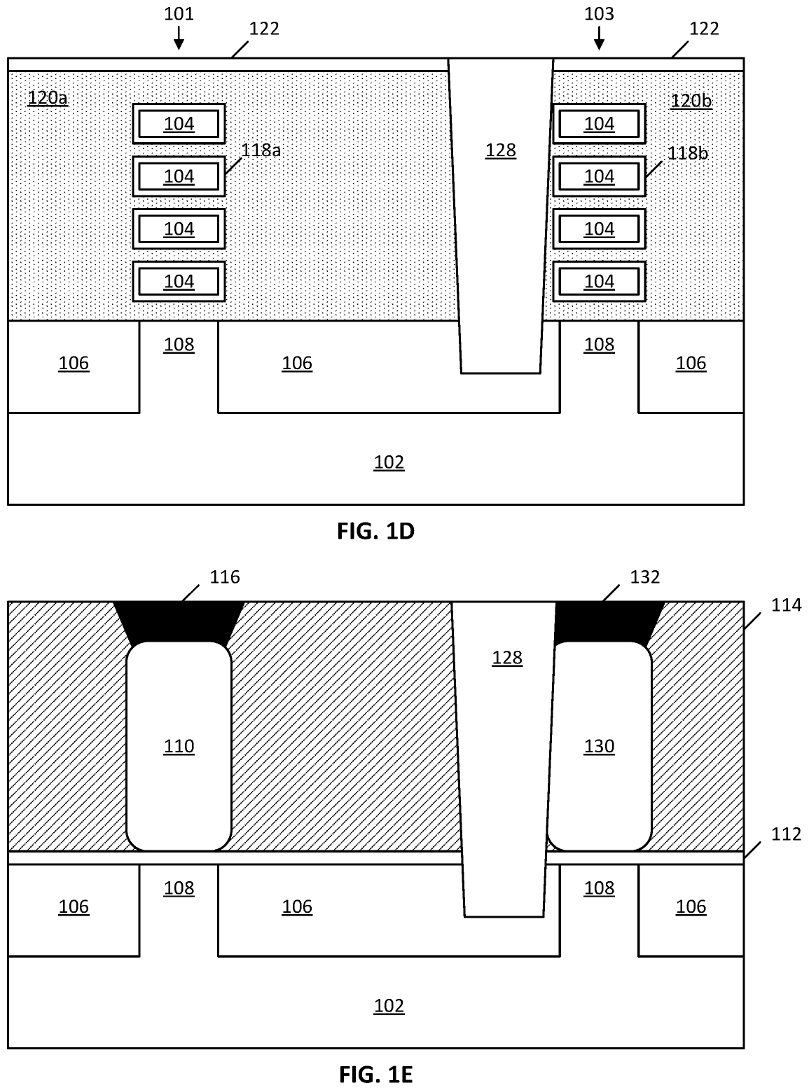

FIG. 1A is a cross-sectional view taken across the gate trench of two example semiconductor devices, a first semiconductor device 101 and a second semiconductor device 103, according to an embodiment of the present disclosure. FIG. 1B is another cross-sectional view taken across the source/drain or diffusion region (and contact trench) adjacent to the gate trench either into or out of the page of FIG. 1A. FIG. 1C is a top-down cross-section view of the adjacent semiconductor devices 101 and 103 taken across the dashed line 1C-1C depicted in both FIG. 1A and FIG. 1B. FIG. 1A illustrates the cross-section taken across the dashed line 1A-1A depicted in FIG. 1C, and FIG. 1B illustrates the cross-section taken across the dashed line 1B-1B depicted in FIG. 1C. It should be noted that some of the material layers (such as dielectric cap 122) are not visible in the top-down view of FIG. 1C, given the location of the depicted cross-section.

Each of semiconductor devices 101 and 103 may be, for example, non-planar metal oxide semiconductor (MOS) transistors, such as tri-gate (e.g., finFET) or gate-all-around (GAA) transistors, although other transistor topologies and types could also benefit from the techniques provided herein. The illustrated example embodiments use the GAA structure. The various illustrated semiconductor devices represent a portion of an integrated circuit that may contain any number of similar semiconductor devices.

As can be seen, semiconductor devices 101 and 103 are formed on a substrate 102. Any number of semiconductor devices can be formed on substrate 102, but four are illustrated here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of (or all of) substrate 102 is removed and replaced with one or more backside interconnect layers to form backside signal and power routing, during a backside process.

Each of semiconductor devices 101 and 103 includes one or more nanoribbons 104 that extend parallel to one another along a direction between source or drain regions 110, as seen more clearly in FIG. 1C (e.g., a first direction into and out of the page in the cross-section view of FIG. 1A). Nanoribbons 104 are one example of semiconductor regions or semiconductor bodies that extend between source or drain regions 110. The term nanoribbon may also encompass other similar shapes such as nanowires or nanosheets. The semiconductor material of nanoribbons 104 may be formed from substrate 102. In some embodiments, semiconductor devices 101 and 103 may each include semiconductor regions in the shape of fins that can be, for example, native to substrate 102 (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitate forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches.

As can further be seen, adjacent semiconductor devices are separated by a dielectric fill 106. Dielectric fill 106 provides shallow trench isolation (STI) between any adjacent semiconductor devices. Dielectric fill 106 can be any suitable dielectric material, such as silicon dioxide, aluminum oxide, or silicon oxycarbonitride.

Semiconductor devices 101 and 103 each include a subfin region 108. According to some embodiments, subfin region 108 comprises the same semiconductor material as substrate 102 and is adjacent to dielectric fill 106. According to some embodiments, nanoribbons 104 (or other semiconductor bodies) extend between source or drain regions 110 in the first direction to provide an active region (sometimes called channel region) for a transistor (e.g., the semiconductor region beneath the gate). It should be understood that the source or drain regions 110 illustrated in the cross-section of FIG. 1B are only along one side of nanoribbons 104 (e.g., out of the page of FIG. 1A) and that similar source or drain regions 110 may be present along the opposite side of nanoribbons 104, as shown in FIG. 1C.

According to some embodiments, source or drain regions 110 are epitaxial regions that are provided using an etch-and-replace process. In other embodiments source or drain regions 110 could be, for example, implantation-doped native portions of the semiconductor fins or substrate. Any semiconductor materials suitable for source and drain regions can be used (e.g., group IV and group III-V semiconductor materials). The composition and doping of source or drain regions 110 may be the same or different, depending on the polarity of the transistors. In an example, for instance, one transistor is a p-type MOS (PMOS) transistor, and the other transistor is an n-type MOS (NMOS) transistor. Any number of source or drain configurations and materials can be used.

According to some embodiments, a lower dielectric layer 112 exists beneath source or drain regions 110. Lower dielectric layer 112 can include any suitable dielectric material, such as silicon dioxide or silicon nitride or silicon oxynitride and may be provided to isolate source or drain regions 110 from subfin regions 108. According to some embodiments, another dielectric fill 114 is provided around and over portions of source or drain regions 110 along the source/drain trench after epitaxial formation of the source/drain regions is complete. Accordingly, each source or drain region 110 may be isolated from any adjacent source or drain regions 110 by dielectric fill 114. Dielectric fill 114 may be any suitable dielectric material, although in some embodiments, dielectric fill 114 includes the same dielectric material as dielectric fill 106 or lower dielectric layer 112. In one example, each of dielectric fill 114, lower dielectric layer 112, and dielectric fill 106 includes silicon dioxide. According to some embodiments, one or more conductive contacts 116 are present on or over one or more corresponding source or drain regions 110. Conductive contacts 116 may be any suitably conductive material such as tungsten (W). Other conductive materials may include copper (Cu), ruthenium (Ru), cobalt (Co), titanium (Ti), molybdenum (Mo), or any alloys thereof.

According to some embodiments, a first gate structure extends over nanoribbons 104 of semiconductor device 101 along a second direction across the page while a second gate structure extends over nanoribbons 104 of semiconductor device 103 along the second direction. Each gate structure includes a respective gate dielectric 118a/118b and a gate layer (or gate electrode) 120a/120b. Gate dielectric 118a/118b represents any number of dielectric layers present between nanoribbons 104 and gate electrode 120a/120b. Gate dielectric 118a/118b may also be present on the surfaces of other structures within the gate trench, such as on subfin region 108. Gate dielectric 118a/118b may include any suitable gate dielectric material(s). In some embodiments, gate dielectric 118a/118b includes a layer of native oxide material (e.g., silicon dioxide) on the nanoribbons or other semiconductor regions making up the channel region of the devices, and a layer of high-k dielectric material (e.g., hafnium oxide) on the native oxide.

Gate electrode 120a/120b may represent any number of conductive layers, such as any metal, metal alloy, or doped polysilicon layers. In some embodiments, gate electrode 120a/120b includes one or more workfunction metals around nanoribbons 104. In some embodiments, one of semiconductor devices 101 and 103 is a p-channel device that include a workfunction metal having titanium around its nanoribbons 104 and the other semiconductor device is an n-channel device that includes a workfunction metal having tungsten around its nanoribbons 104. Gate electrode 120a/120b may also include a fill metal or other conductive material around the workfunction metals to provide the whole gate electrode structure. According to some embodiments, the gate structures (or more specifically gate electrodes 120a/120b) include a dielectric cap 122. Dielectric cap 122 may include any suitable dielectric material, such as silicon nitride, and may have a thickness between about 10 nm and about 20 nm. According to some embodiments, a top surface of dielectric cap 122 is substantially coplanar with a top surface of dielectric fill 114.

As further shown in this example, adjacent gate structures may be separated along the second direction (e.g., across the page) by a gate cut 124, which acts like a dielectric barrier between gate structures. Gate cut 124 may include a sufficiently insulating material, such as any suitable dielectric material. Example dielectric materials for gate cut 124 include silicon nitride, silicon dioxide, silicon carbide, or silicon oxynitride. According to some embodiments, gate cut 124 also extends in the first direction (into and out of the page) such that it may also separate adjacent source or drain regions 110. In some examples, gate cut 124 also cuts into at least a portion of source or drain regions 110 and/or a portion of conductive contacts 116 (such as shown in FIG. 1E). According to some embodiments, gate cut 124 is formed after the formation of the gate structures, and as such, gate cut 124 does not have gate dielectric 118a/118b along its sidewalls. Due to the fabrication process for gate cut 124 which involves one or more CMP steps, a top surface of gate cut 124 is substantially coplanar with a top surface of conductive contacts 116. Furthermore, the top surface of gate cut 124 may also be substantially coplanar with a top surface of dielectric cap 122.

FIG. 1C illustrates a plan view of the integrated circuit showing how gate cut 124 cuts across the gate trench isolating gate electrode 120a from gate electrode 120b. According to some embodiments, spacer structures 126 extend along the sides of the gate trench and isolate the gate trench from the source/drain trench (including epi regions and their respective contacts). Spacer structures 126 may include any suitable dielectric material, such as silicon nitride. The nanoribbons 104 (or other channel body) extend through spacer structures 126 to contact respective source or drain regions 110.

As noted above, the gate cut may be aligned so closely to a semiconductor device that the gate cut intersects the source or drain region and/or the conductive contact over the source or drain region. FIGS. 1D and 1E are cross-sectional views across two semiconductor devices and a gate cut 128 that are similar to the structure shown in FIGS. 1A and 1B. However, in this example, gate cut 128 is aligned very close to the second semiconductor device 103 such that it contacts at least a portion of source or drain region 130 and at least a portion of conductive contact 132. Any of the embodiments discussed herein for forming a gate cut can be used for forming either gate cut 128 from FIGS. 1D and 1E or gate cut 124 from FIGS. 1A and 1B.

### Fabrication Methodology

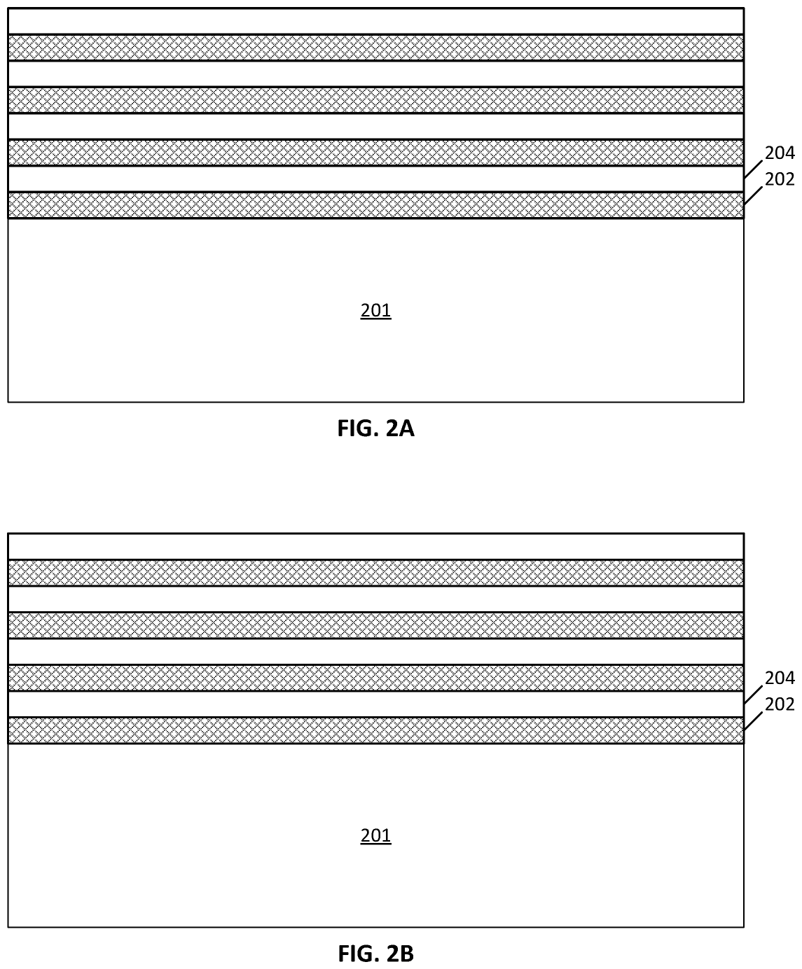

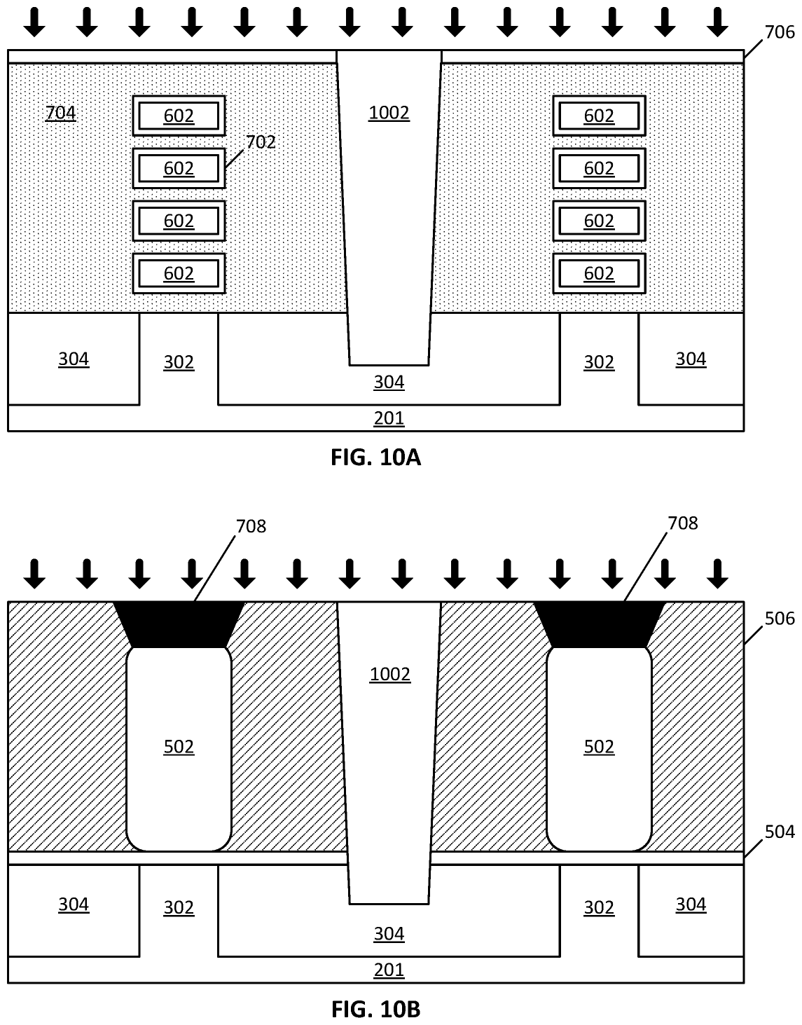

FIGS. 2A-10A and 2B—10B are cross-sectional views that collectively illustrate a first example process for forming an integrated circuit configured with a gate cut having a top surface substantially coplanar with source or drain contacts, in accordance with an embodiment of the present disclosure. FIGS. 2A-10A represent cross-sectional views taken across a gate trench of the integrated circuit, while FIGS. 2B-10B represent cross-sectional views taken across the source/drain trench adjacent to the gate trench along the same direction. Each figure shows an example structure that results from the process flow up to that point in time, so the depicted structure evolves as the process flow continues, culminating in the structure shown in FIGS. 10A and 10B, which is similar to the structure shown in FIGS. 1A and 1B, respectively. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow. Although the fabrication of a single gate cut is illustrated in the aforementioned figures, it should be understood that any number of similar gate cuts can be fabricated across the integrated circuit using the same processes discussed herein.

FIGS. 2A and 2B illustrate parallel cross-sectional views taken through a stack of alternating semiconductor layers on a semiconductor substrate 201. FIG. 2A is taken across a portion of the stack that will eventually become a gate trench while FIG. 2B is taken across a portion of the stack that will eventually become a source/drain trench adjacent and parallel to the gate trench. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

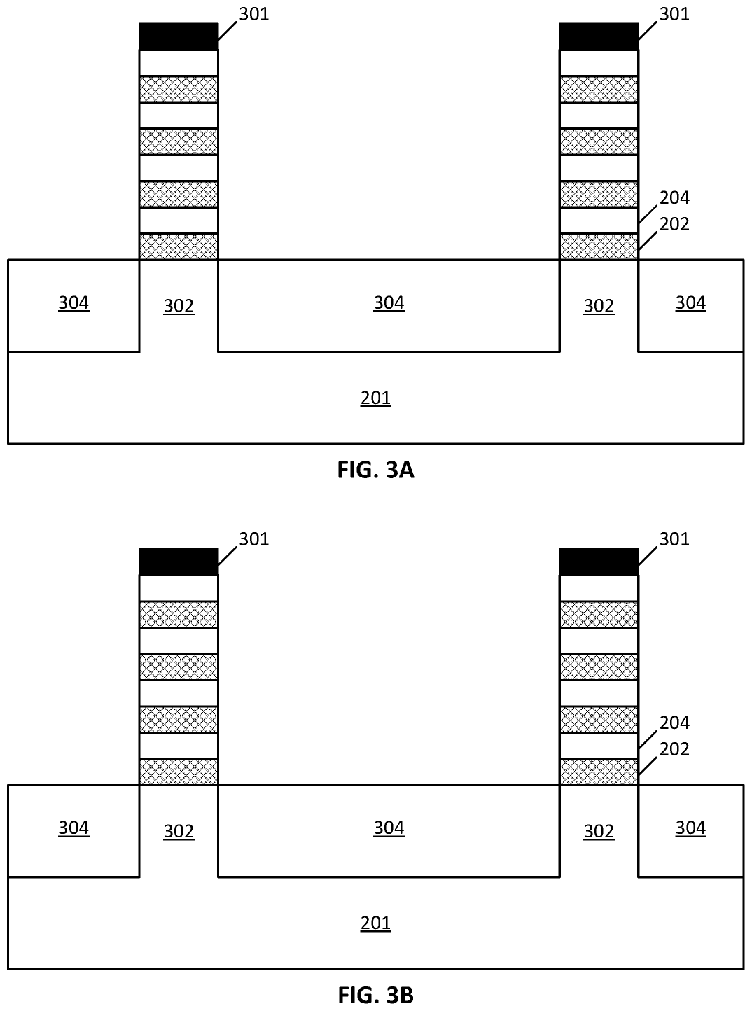

FIGS. 3A and 3B depict the cross-section views of the structure shown in FIGS. 2A and 2B, respectively, following the formation of a cap layer 301 and the subsequent formation of fins beneath cap layer 301, according to an embodiment. Cap layer 301 may be any suitable hard mask material such as a carbon hard mask (CHM) or silicon nitride. Cap layer 301 is patterned into rows to form corresponding rows of fins from the alternating layer stack of sacrificial layers 202 and semiconductor layers 204. The rows of fins extend lengthwise in a first direction (e.g., into and out of the page of each cross-section view).

According to some embodiments, an anisotropic etching process through the layer stack continues into at least a portion of substrate 201, where the unetched portions of substrate 201 beneath the fins form subfin regions 302. The etched portions of substrate 201 may be filled with a dielectric fill 304 that acts as shallow trench isolation (STI) between adjacent fins. Dielectric fill 304 may be any suitable dielectric material such as silicon dioxide, and may be recessed to a desired depth as shown (in this example case, down to around the upper surface of the subfins), so as to define the active portion of the fins that will be covered by a gate structure.

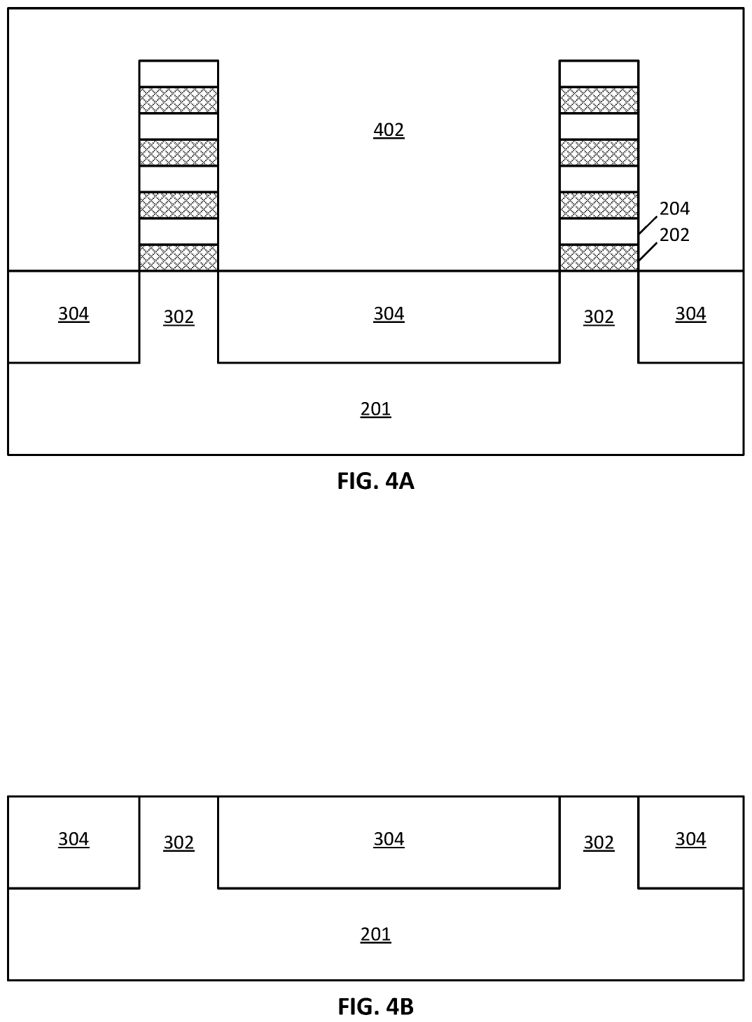

FIGS. 4A and 4B depict the cross-section views of the structure shown in FIGS. 3A and 3B, respectively, following the formation of a sacrificial gate 402 extending across the fins in a second direction different from the first direction, according to some embodiments. Sacrificial gate 402 may extend across the fins in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fins. In some examples, sacrificial gate 402 includes polysilicon.

As seen in the cross-section views, sacrificial gate 402 extends across the fins along the gate trench cross-section of FIG. 4A but is not present along the source/drain trench cross-section of FIG. 4B. Accordingly, sacrificial gate 402 (along with any gate spacers formed on the sidewalls of sacrificial gate 402) protect the underlying portions of the fins while the exposed portions of the fins are etched away as seen in FIG. 4B. According to some embodiments, both semiconductor layers 204 and sacrificial layers 202 are etched at substantially the same rate using an anisotropic RIE process. As observed in FIG. 4B, the fins are completely removed above subfin regions 302. In some embodiments, the RIE process may also etch into subfin regions 302 thus recessing subfin regions 302 beneath a top surface of dielectric fill 304.

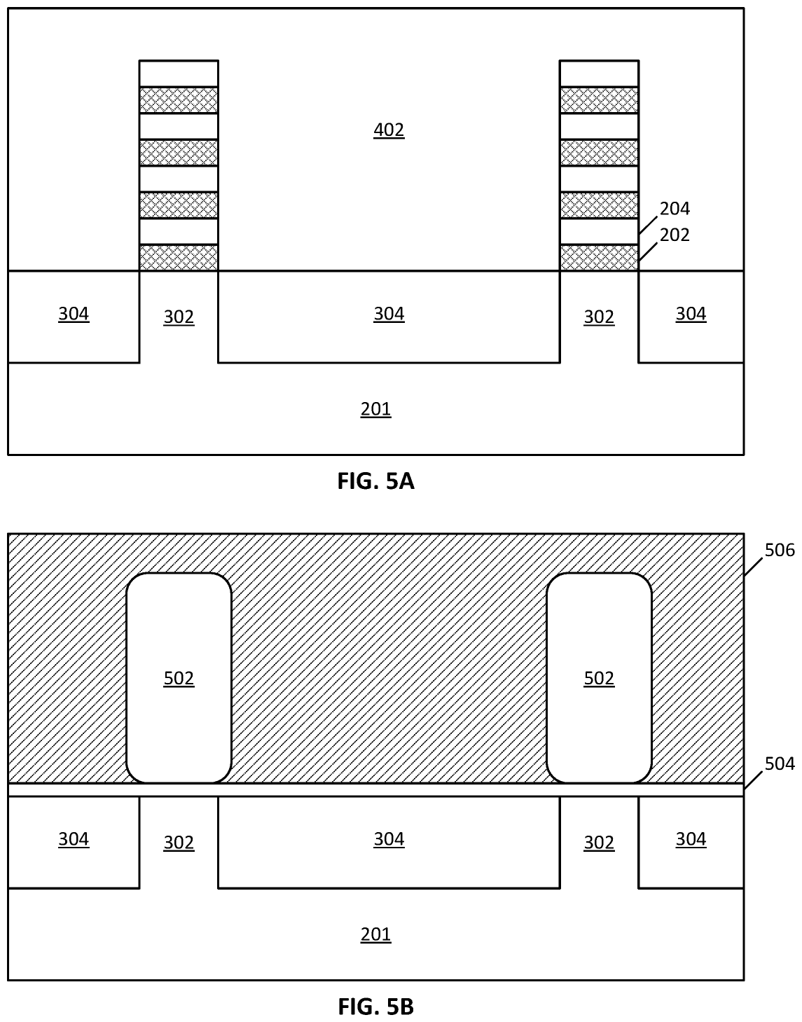

FIGS. 5A and 5B depict the cross-section views of the structure shown in FIGS. 4A and 4B, respectively, following the formation of source or drain regions 502 at the ends of each of the fins (extending into and out of the page in FIG. 5A), according to some embodiments. Source or drain regions 502 may be epitaxially grown from the exposed ends of semiconductor layers 204, such that the material grows together or otherwise merges towards the middle of the trenches between fins, according to some embodiments. Note that epitaxial growth on one semiconductor layer 204 can fully or partially merge with epitaxial growth on one or more other semiconductor layers 204 in the same vertical stack. The degree of any such merging can vary from one embodiment to the next. In the example of a PMOS device, a given source or drain region 502 may be a semiconductor material (e.g., group IV or group III-V semiconductor materials) having a higher dopant concentration of p-type dopants compared to n-type dopants. In the example of an NMOS device, a given source or drain region 502 may be a semiconductor material (e.g., group IV or group III-V semiconductor materials) having a higher dopant concentration of n-type dopants compared to p-type dopants. According to some embodiments, the various source or drain regions 502 grown from different semiconductor devices may be aligned along the second direction as shown in FIG. 5B.

According to some embodiments, a bottom dielectric layer 504 may be deposited prior to the formation of source or drain regions 502. Bottom dielectric layer 504 may be any suitable dielectric material, such as silicon dioxide, silicon nitride, or silicon oxynitride. Bottom dielectric layer 504 may be included to provide isolation between source or drain regions 502 and subfin regions 302.

According to some embodiments, another dielectric fill 506 is provided along the source/drain trench. Dielectric fill 506 may extend between adjacent ones of the source or drain regions 502 along the second direction and also may extend up and over each of the source or drain regions 502, according to some embodiments. Accordingly, each source or drain region 502 may be isolated from any adjacent source or drain regions 502 by dielectric fill 506. Dielectric fill 506 may be any suitable dielectric material, although in some embodiments, dielectric fill 506 includes the same dielectric material as dielectric fill 304 or bottom dielectric layer 504. In one example, each of dielectric fill 506, bottom dielectric layer 504, and dielectric fill 304 includes silicon dioxide. Dielectric fill 506 may not be present between certain adjacent source or drain regions in situations where the adjacent source or drain regions are desired to be electrically coupled together. According to some embodiments, a top surface of dielectric fill 506 may be polished using, for example, chemical mechanical polishing (CMP). The top surface of dielectric fill 506 may be polished until it is substantially coplanar with a top surface of sacrificial gate 402. In some embodiments, inner gate spacers can be formed after the source/drain trenches are etched and before the epitaxial deposition is performed. For instance, a selective etch can be used to laterally recess sacrificial layers 202, and that recess can then be filled with inner gate spacer material (e.g., silicon nitride or silicon oxynitride). Any excess gate spacer material can be removed with directional etching.

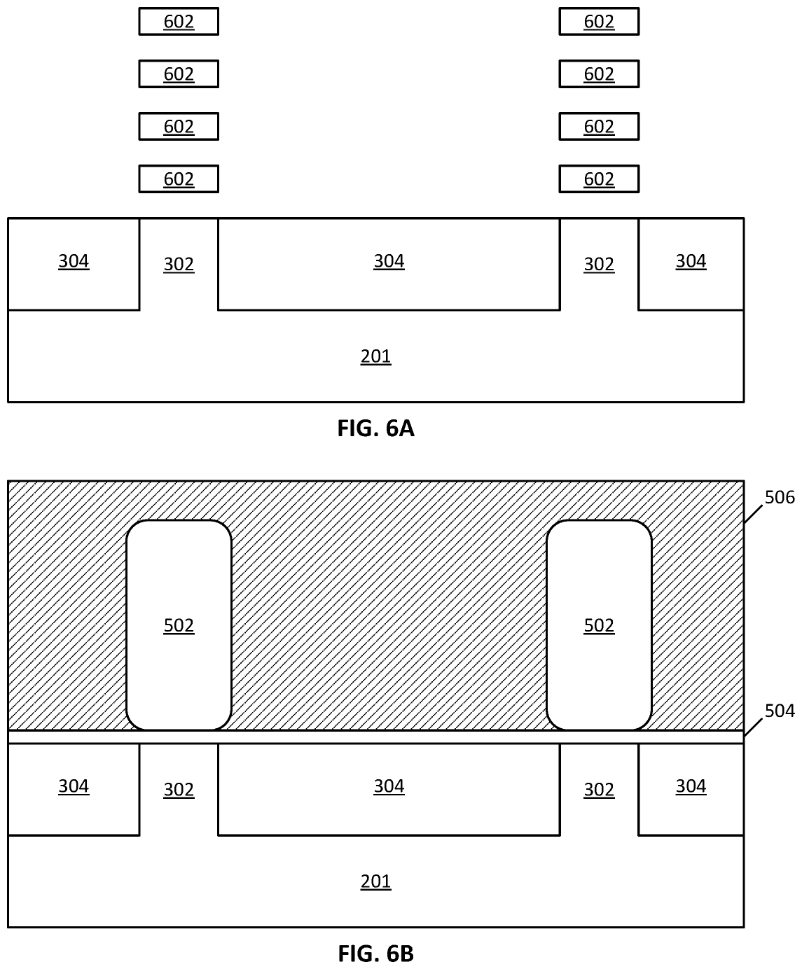

FIGS. 6A and 6B depict the cross-section views of the structure shown in FIGS. 5A and 5B, respectively, following the formation of nanoribbons 602 from semiconductor layers 204, according to some embodiments. Depending on the dimensions of the structures, nanoribbons 602 may also be considered nanowires or nanosheets. Sacrificial gate 402 may be removed using any wet or dry isotropic process thus exposing the alternating layer stack of the fins within the trenches left behind after the removal of sacrificial gate 402. Once sacrificial gate 402 is removed, sacrificial layers 202 may also be removed using a selective isotropic etching process that removes the material of sacrificial layers 202 but does not remove (or removes very little of) semiconductor layers 204 or any other exposed layers (e.g., inner gate spacers). At this point, the suspended (sometimes called released) semiconductor layers 204 form nanoribbons 602 that extend in the first direction (into and out of the page) between a first source or drain region 502 and a second source or drain region on the opposite ends of nanoribbons 602.

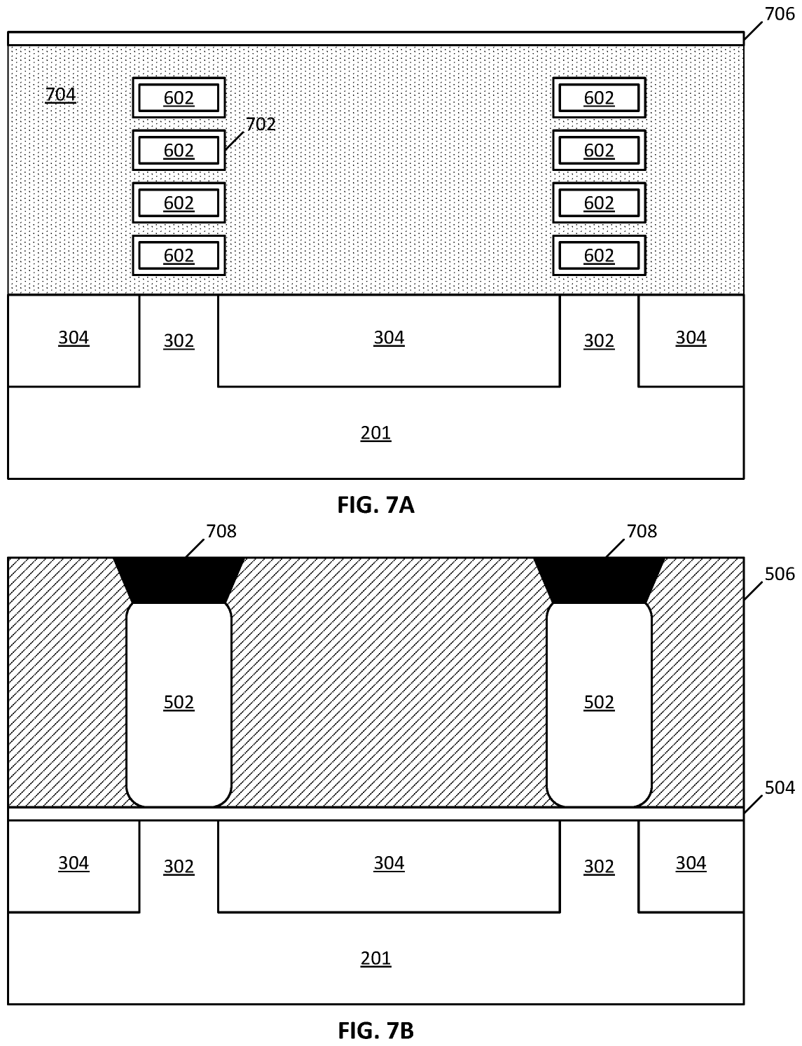

FIGS. 7A and 7B depict the cross-section views of the structure shown in FIGS. 6A and 6B, respectively, following the formation of a gate structure around nanoribbons 602 within the gate trench, according to some embodiments. As noted above, the gate structure includes a gate dielectric 702 and a gate electrode 704. Gate dielectric 702 may be conformally deposited around nanoribbons 602 using any suitable deposition process, such as atomic layer deposition (ALD). Gate dielectric 702 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 702 is hafnium oxide with a thickness between about 1 nm and about 5 nm. In some embodiments, gate dielectric 702 may include one or more silicates (e.g., titanium silicate, tungsten silicate, niobium silicate, and silicates of other transition metals). Gate dielectric 702 may be a multilayer structure, in some examples. For instance, gate dielectric 702 may include a first layer on nanoribbons 602, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 702 to improve its quality when a high-k dielectric material is used. In some embodiments, the high-k material can be nitridized to improve its aging resistance.

Gate electrode 704 may be deposited over gate dielectric 702 and can be any standard or proprietary conductive structure. In some embodiments, gate electrode 704 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 704 may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. According to some embodiments, gate electrode 704 is recessed and the recessed portion is filled with a dielectric material to form a dielectric cap 706. Any suitable dielectric material may be used for dielectric cap 706, such as any high-k dielectric material. In some embodiments, dielectric cap 706 includes silicon nitride. Dielectric cap 706 may have a thickness between about 10 nm and about 20 nm and be deposited using CVD.

According to some embodiments, recesses may be formed through dielectric fill 506 in the source/drain trench to reveal portions of source or drain regions 502. These recesses may then be filled with conductive material to form conductive contacts 708. Any suitable metal or metal alloy may be used for the conductive material. According to some embodiments, a top surface of conductive contacts 708 may be polished using, for example, CMP. The top surface of conductive contacts 708 may be polished until it is substantially coplanar with a top surface of dielectric fill 506.

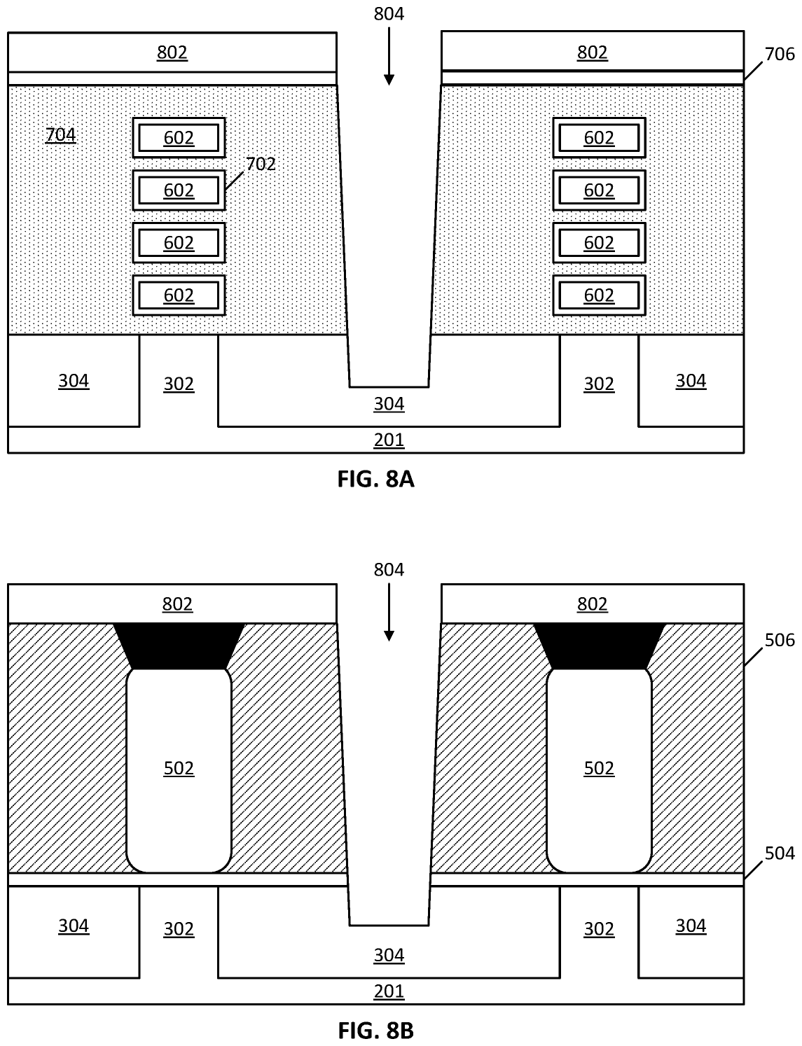

FIGS. 8A and 8B depict the cross-section views of the structure shown in FIGS. 7A and 7B, respectively, following the formation of a mask structure 802 and a gate cut recess 804 through a thickness of the gate structure, according to some embodiments. Mask structure 802 may include any number of suitable dielectric layers and may have a thickness between about 40 nm and about 60 nm or between about 5 nm and about 100 nm. For example, mask structure 802 may include silicon nitride or silicon dioxide. In some embodiments, mask structure 802 includes a first layer of silicon nitride and a second layer of silicon dioxide on the first layer. According to an embodiment, an opening is first formed through mask structure 802 (and through dielectric cap 706) to define the location of the gate cut recess. A separate etching process may then be performed through the opening in mask structure 802 that iteratively etches through portions of gate electrode 704 while simultaneously protecting the sidewalls of the recess from lateral etching to provide a high height-to-width aspect ratio final gate cut recess 804 (e.g., aspect ratio of 5:1 or higher). Gate cut recess 804 may extend into at least a portion of dielectric fill 304 or even deeper into a portion of the underlying substrate 201.

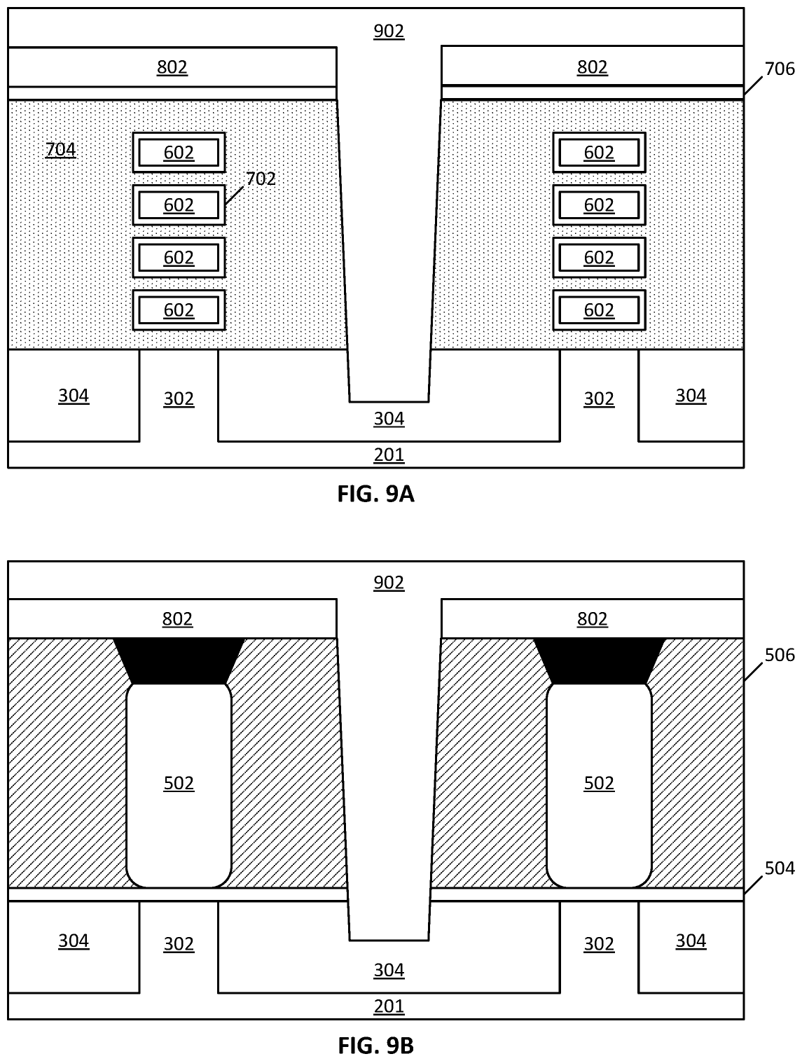

FIGS. 9A and 9B depict the cross-section views of the structure shown in FIGS. 8A and 8B, respectively, following the formation of a dielectric material 902 within gate cut recess 804, according to some embodiments. Dielectric material 902 may be deposited using ALD or a flowable process to substantially fill gate cut recess 804 and also form out on the top surface of mask structure 802. According to some embodiments, dielectric material 902 may be the same as the dielectric material of mask structure 802. For example, both mask structure 802 and dielectric material 902 may be silicon nitride or both mask structure 802 and dielectric material 902 may be silicon dioxide. In the case of dielectric material 902 being silicon dioxide, a thin layer of a high-k dielectric material, such as silicon nitride, may be first deposited within gate cut recess 804 to protect the metal gate electrode 704 from oxidation.

FIGS. 10A and 10B depict the cross-section views of the structure shown in FIGS. 9A and 9B, respectively, following a polishing process using CMP as indicated by the bold arrows, according to some embodiments. The CMP process removes both mask structure 802 and dielectric material 902 outside of gate cut recess 804 to ultimately form gate cut 1002 from the dielectric material remaining within gate cut recess 804. Since both mask structure 802 and dielectric material 902 are the same dielectric material in this example, a single CMP process may be used to polish through both layers until a top surface of conductive contacts 708 is exposed. This polishing process yields a top surface of gate cut 1002 that is substantially coplanar with a top surface of conductive contacts 708 and a top surface of dielectric cap 706.

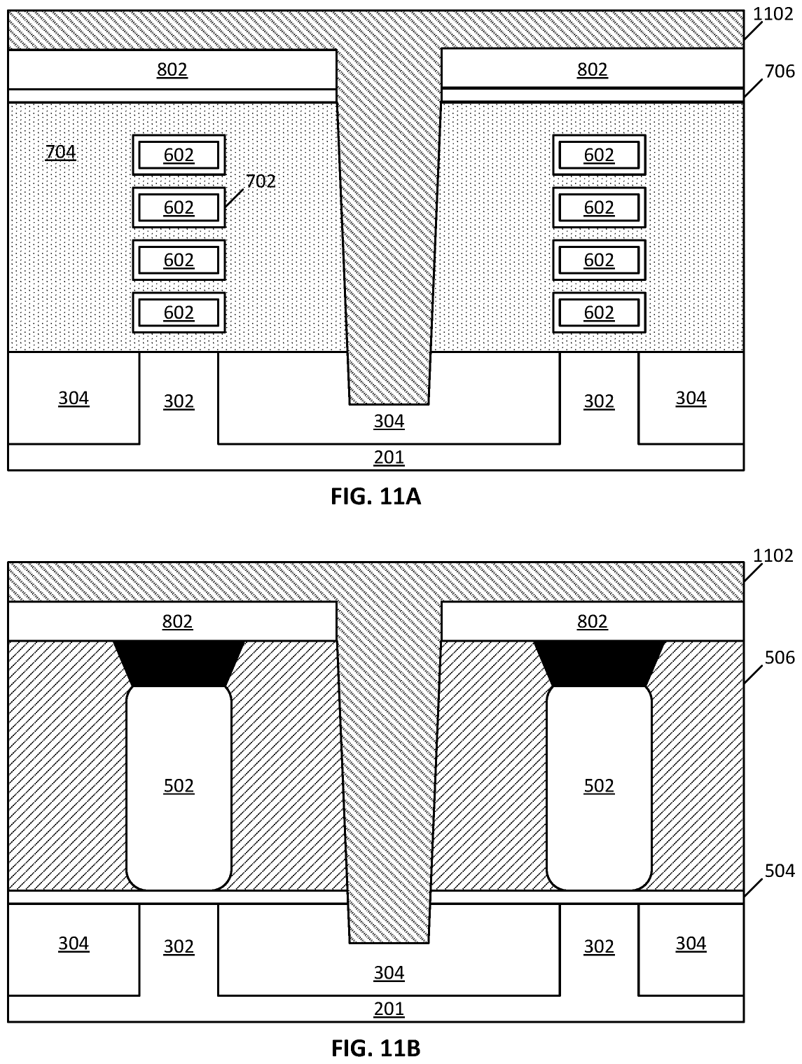

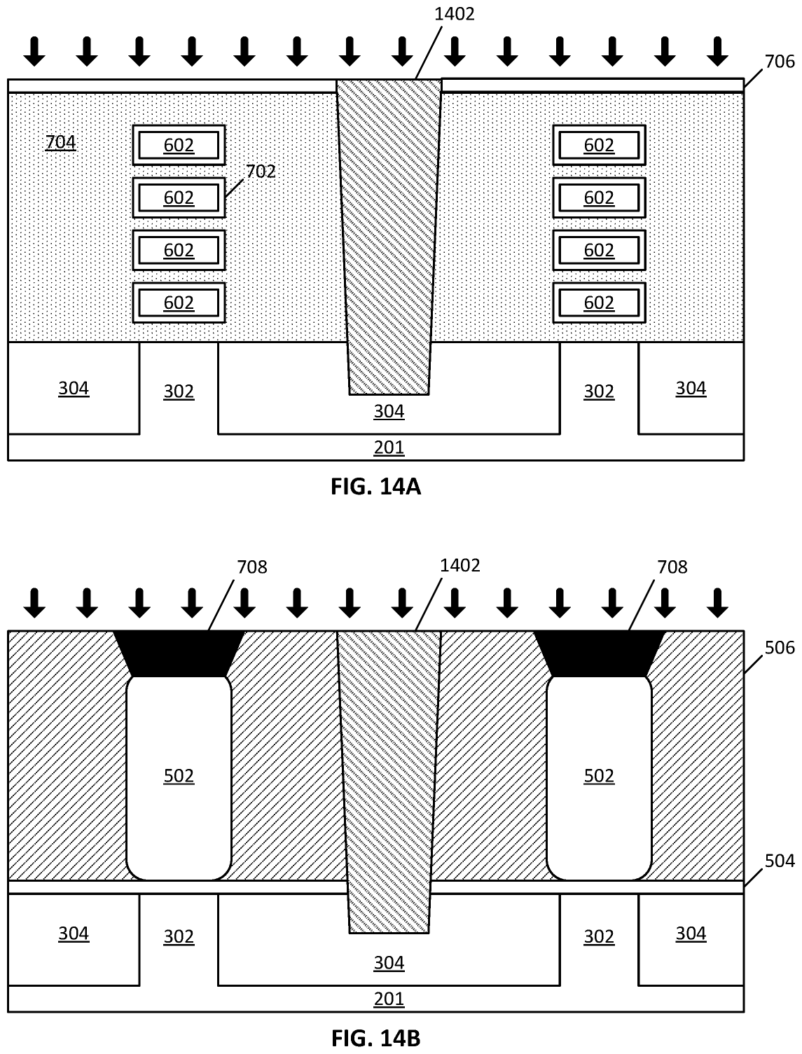

FIGS. 11A-14A and 11B—14B are cross-sectional views that collectively illustrate a second example process for forming an integrated circuit configured with a gate cut having a top surface substantially coplanar with source or drain contacts, in accordance with an embodiment of the present disclosure. Each figure shows an example structure that results from a process flow starting from FIGS. 8A and 8B, so the depicted structure evolves as the process flow continues, culminating in the structure shown in FIGS. 14A and 14B.

FIGS. 11A and 11B depict the cross-section views of the structure shown in FIGS. 8A and 8B, respectively, following the formation of a dielectric material 1102 within gate cut recess 804, according to some embodiments. Dielectric material 1102 may be deposited using CVD to substantially fill gate cut recess 804 and also form out on the top surface of mask structure 802. According to some embodiments, dielectric material 1102 has a different dielectric material compared to mask structure 802. For example, dielectric material 1102 may be silicon dioxide while mask structure 802 is silicon nitride. As noted above, a thin layer of a high-k dielectric material, such as silicon nitride, may be first deposited within gate cut recess 804 to protect the metal gate electrode 704 from oxidation through deposition of dielectric material 1102. Since dielectric material 1102 and mask structure 802 are different materials, a single selective CMP process may not be performed to polish through both layers.

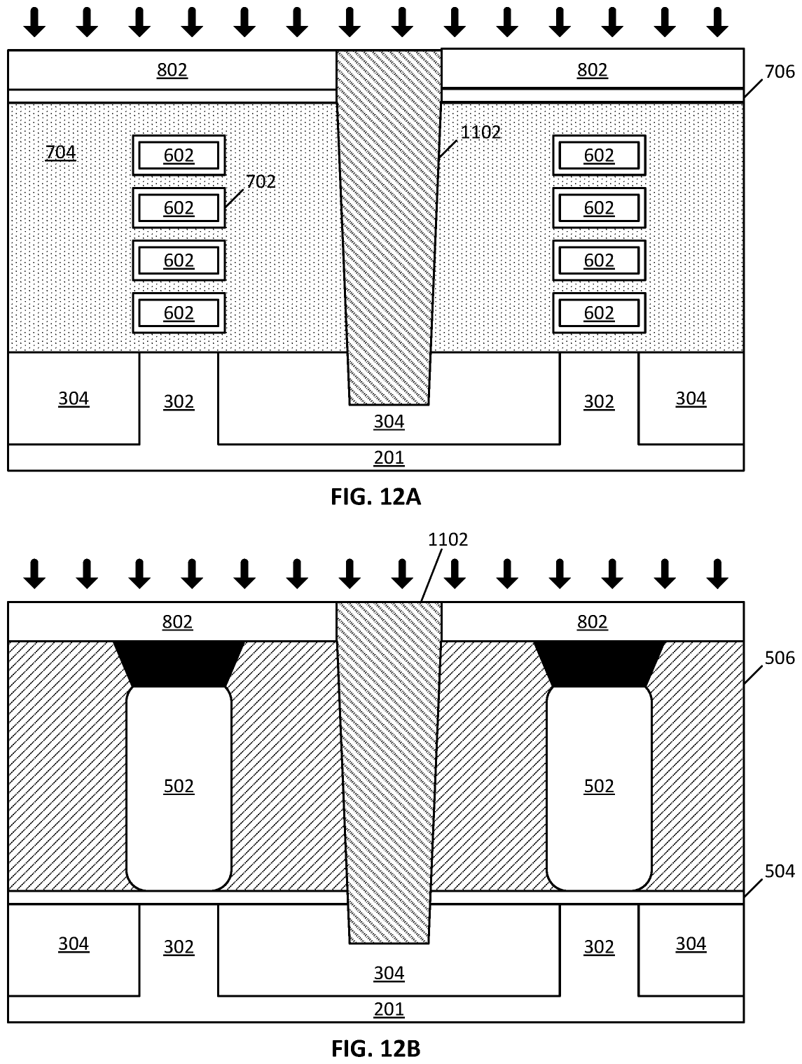

FIGS. 12A and 12B depict the cross-section views of the structure shown in FIGS. 11A and 11B, respectively, following a first polishing process using CMP to remove a top portion of dielectric material 1102, according to some embodiments. The CMP process may be tuned to stop once the dielectric material of mask structure 802 is exposed. For example, the CMP process may be tuned to polish silicon dioxide and stop once silicon nitride is exposed. According to some embodiments, dielectric material 1102 is polished until a top surface of dielectric material 1102 is substantially coplanar with a top surface of mask structure 802.

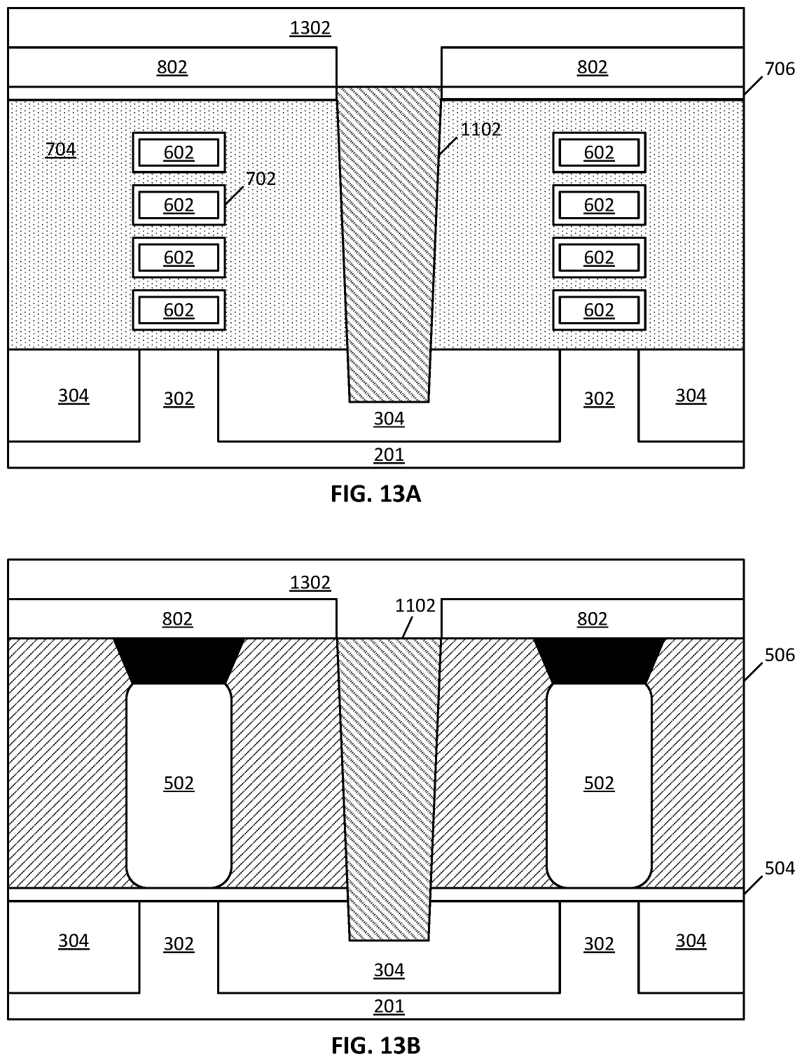

FIGS. 13A and 13B depict the cross-section views of the structure shown in FIGS. 12A and 12B, respectively, following a recessing of dielectric material 1102 and deposition of a capping layer 1302 within at least the recessed area, according to some embodiments. Because dielectric material 1102 and mask structure 802 are different materials in this example, dielectric material 1102 may be selectively etched using any wet or dry etch chemistry. In some examples, dielectric material 1102 may be etched until its top surface is substantially coplanar with a bottom surface of mask structure 802. In some examples, dielectric material 1102 may be etched until its top surface is at least below a bottom surface of mask structure 802.

Following the recessing of dielectric material 1102, the recessed volume that had been taken up by dielectric material 1102 may be filled or mostly filled with capping layer 1302. According to some embodiments, capping layer 1302 is deposited using CVD or ALD and may be the same material as mask structure 802. For example, both mask structure 802 and capping layer 1302 may include silicon nitride. Capping layer 1302 may also form on the top surface of mask structure 802, as illustrated.

FIGS. 14A and 14B depict the cross-section views of the structure shown in FIGS. 13A and 13B, respectively, following a second polishing process using CMP to remove both capping layer 1302 and mask structure 802, according to some embodiments. A selective CMP process may be used to remove both layers as they are the same dielectric material (e.g., silicon nitride). The CMP process ultimately forms gate cut 1402 from the dielectric material remaining within gate cut recess 804. The CMP process may polish through capping layer 1302 and mask structure 802 until a top surface of conductive contacts 708 is exposed. This polishing process yields a top surface of gate cut 1402 that is substantially coplanar with a top surface of conductive contacts 708 and a top surface of dielectric cap 706.

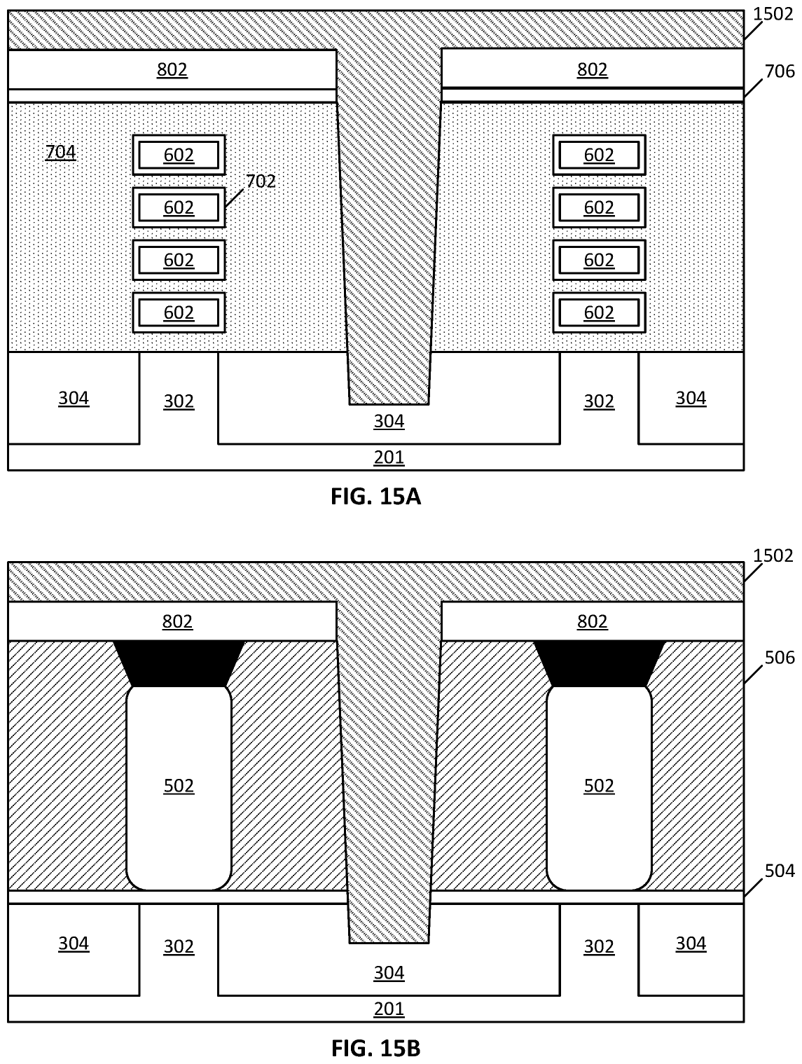

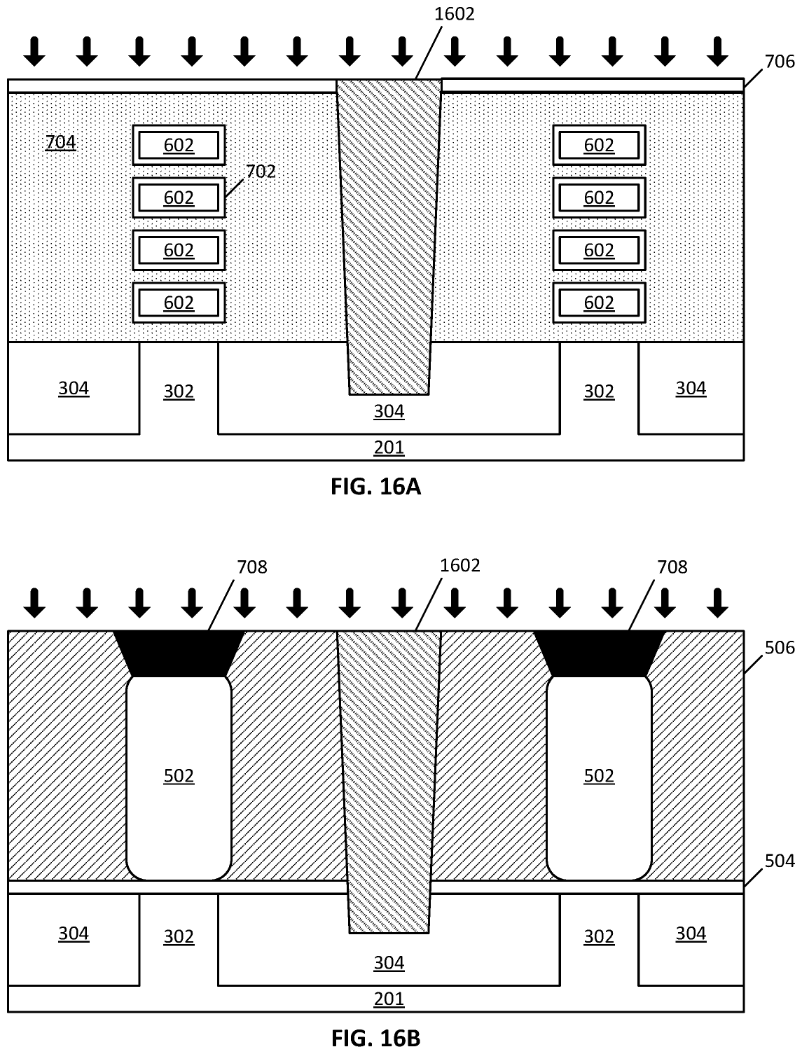

FIGS. 15A-16A and 15B—16B are cross-sectional views that collectively illustrate a third example process for forming an integrated circuit configured with a gate cut having a top surface substantially coplanar with source or drain contacts, in accordance with an embodiment of the present disclosure. Each figure shows an example structure that results from a process flow starting from FIGS. 8A and 8B, so the depicted structure evolves as the process flow continues, culminating in the structure shown in FIGS. 15A and 15B.

FIGS. 15A and 15B depict the cross-section views of the structure shown in FIGS. 8A and 8B, respectively, following the formation of a dielectric material 1502 within gate cut recess 804, according to some embodiments. Dielectric material 1502 may be deposited using CVD to substantially fill gate cut recess 804 and also form out on the top surface of mask structure 802. According to some embodiments, dielectric material 1502 has a different dielectric material compared to mask structure 802. For example, dielectric material 1502 may be silicon dioxide while mask structure 802 is silicon nitride. As noted above, a thin layer of a high-k dielectric material, such as silicon nitride, may be first deposited within gate cut recess 804 to protect the metal gate electrode 704 from oxidation through deposition of dielectric material 1502.

FIGS. 16A and 16B depict the cross-section views of the structure shown in FIGS. 15A and 15B, respectively, following a nonselective polishing process using CMP to remove both mask structure 802 and dielectric material 1502 outside of gate cut recess 804 to ultimately form gate cut 1602 from the dielectric material remaining within gate cut recess 804. Since the polishing process is nonselective, it may proceed through both mask structure 802 and portions of dielectric material 1502 even though they are different materials. However, the process must be carefully controlled to stop at or near the top surface of conductive contacts 708. In some embodiments, a first selective CMP process may be used to remove just the dielectric material 1502 over mask structure 802, and a second nonselective CMP process may be used to remove the remaining portion of dielectric material 1502 and mask structure 802 together. Regardless of which process is used, The polishing procedure yields a top surface of gate cut 1602 that is substantially coplanar with a top surface of conductive contacts 708 and a top surface of dielectric cap 706.

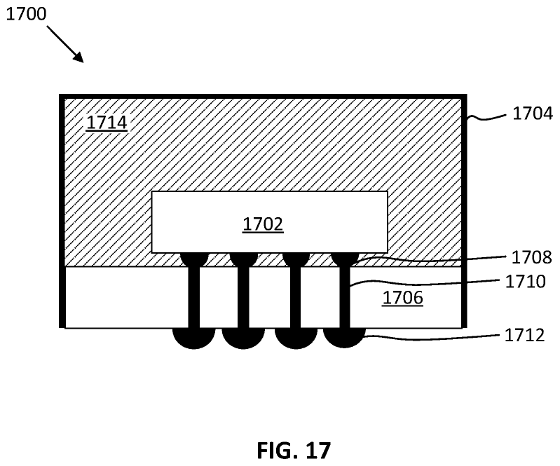

FIG. 17 illustrates an example embodiment of a chip package 1700, in accordance with an embodiment of the present disclosure. As can be seen, chip package 1700 includes one or more dies 1702. One or more dies 1702 may include at least one integrated circuit having semiconductor devices, such as any of the semiconductor devices disclosed herein. One or more dies 1702 may include any other circuitry used to interface with other devices formed on the dies, or other devices connected to chip package 1700, in some example configurations.

As can be further seen, chip package 1700 includes a housing 1704 that is bonded to a package substrate 1706. The housing 1704 may be any standard or proprietary housing, and may provide, for example, electromagnetic shielding and environmental protection for the components of chip package 1700. The one or more dies 1702 may be conductively coupled to a package substrate 1706 using connections 1708, which may be implemented with any number of standard or proprietary connection mechanisms, such as solder bumps, ball grid array (BGA), pins, or wire bonds, to name a few examples. Package substrate 1706 may be any standard or proprietary package substrate, but in some cases includes a dielectric material having conductive pathways (e.g., including conductive vias and lines) extending through the dielectric material between the faces of package substrate 1706, or between different locations on each face. In some embodiments, package substrate 1706 may have a thickness less than 1 millimeter (e.g., between 0.1 millimeters and 0.5 millimeters), although any number of package geometries can be used. Additional conductive contacts 1712 may be disposed at an opposite face of package substrate 1706 for conductively contacting, for instance, a printed circuit board (PCB). One or more vias 1710 extend through a thickness of package substrate 1706 to provide conductive pathways between one or more of connections 1708 to one or more of contacts 1712. Vias 1710 are illustrated as single straight columns through package substrate 1706 for ease of illustration, although other configurations can be used (e.g., damascene, dual damascene, through-silicon via, or an interconnect structure that meanders through the thickness of substrate 1706 to contact one or more intermediate locations therein). In still other embodiments, vias 1710 are fabricated by multiple smaller stacked vias, or are staggered at different locations across package substrate 1706. In the illustrated embodiment, contacts 1712 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1712, to inhibit shorting.

In some embodiments, a mold material 1714 may be disposed around the one or more dies 1702 included within housing 1704 (e.g., between dies 1702 and package substrate 1706 as an underfill material, as well as between dies 1702 and housing 1704 as an overfill material). Although the dimensions and qualities of the mold material 1714 can vary from one embodiment to the next, in some embodiments, a thickness of mold material 1714 is less than 1 millimeter. Example materials that may be used for mold material 1714 include epoxy mold materials, as suitable. In some cases, the mold material 1714 is thermally conductive, in addition to being electrically insulating.

### Methodology

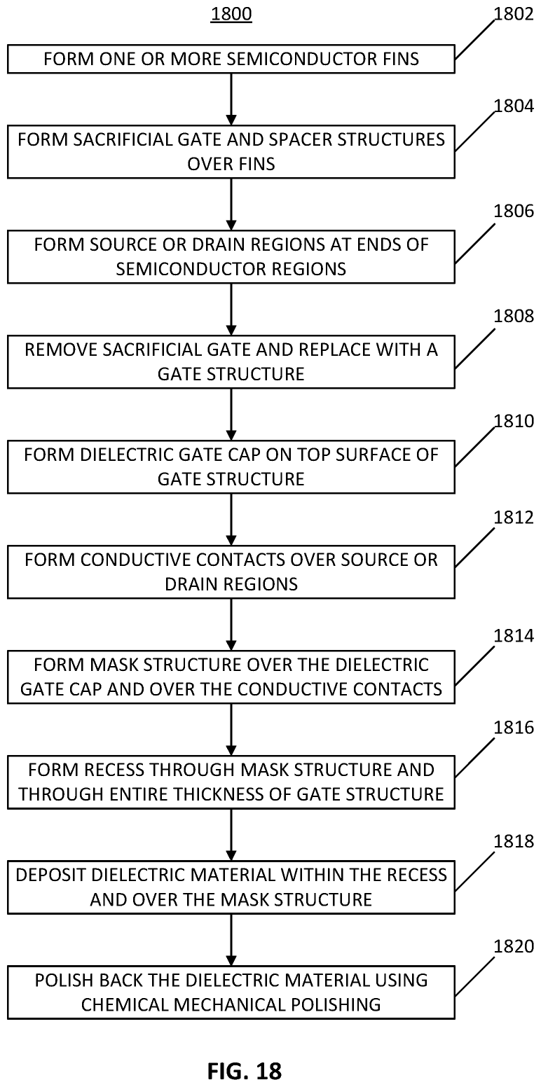

FIG. 18 is a flow chart of a method 1800 for forming at least a portion of an integrated circuit, according to an embodiment. Various operations of method 1800 may be illustrated in FIGS. 2A-16A and FIGS. 2B-16B. However, the correlation of the various operations of method 1800 to the specific components illustrated in the aforementioned figures is not intended to imply any structural and/or use limitations. Rather, the aforementioned figures provide one example embodiment of method 1800. Other operations may be performed before, during, or after any of the operations of method 1800. For example, method 1800 does not explicitly describe all processes that are performed to form common transistor structures. Some of the operations of method 1800 may be performed in a different order than the illustrated order.

Method 1800 begins with operation 1802 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 1800 continues with operation 1804 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 1800 continues with operation 1806 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions.

Method 1800 continues with operation 1808 where the sacrificial gate is removed and replaced with a gate structure. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples.

Method 1800 continues with operation 1810 where a dielectric gate cap is formed on a stop surface of the gate structure. According to some embodiments, the gate electrode may be recessed, and the dielectric gate cap is formed within the recessed area. The dielectric gate cap may have a thickness between 10 nm and 20 nm, such as around 15 nm.

Method 1800 continues with operation 1812 where conductive contacts are formed on the source or drain regions. According to some embodiments, recesses may be formed through the dielectric fill over the top surface of the source or drain regions in the source/drain trench to reveal portions of source or drain regions. These recesses may then be filled with any number of conductive material layers to form the conductive contacts. Any suitable metal or metal alloy may be used for the conductive material layers. According to some embodiments, a top surface of the conductive contacts may be polished using, for example, CMP. The top surface of the conductive contacts may be polished until it is substantially coplanar with a top surface of the adjacent dielectric fill in the source/drain trench.

Method 1800 continues with operation 1814 where a mask structure is formed over the dielectric gate cap and over the conductive contacts. The mask structure may include any suitable dielectric material and may have a thickness between about 40 nm and about 60 nm. For example, the mask structure may be silicon nitride or silicon dioxide.

Method 1800 continues with operation 1816 where a gate cut recess is formed through the mask structure and through an entire thickness of the underlying gate structure. According to some embodiments, the gate cut recess is also formed through a thickness of the dielectric gate cap between the mask structure and the gate structure. According to an embodiment, an opening is first formed through the mask structure (and through the dielectric gate cap) to define the location of the gate cut recess. A separate etching process may then be performed through the opening in the mask structure that iteratively etches through portions of the gate electrode while simultaneously protecting the sidewalls of the recess from lateral etching to provide a high height-to-width aspect ratio gate cut recess (e.g., aspect ratio of 5:1 or higher). The gate cut recess may extend into at least a portion of the dielectric fill between semiconductor fins or even deeper into a portion of the underlying substrate.

Method 1800 continues with operation 1818 where a dielectric material is formed within the gate cut recess and on a top surface of the mask structure. The dielectric material may be deposited using CVD and may be the same material as the mask structure. For example, both the dielectric material and the mask structure can be silicon nitride or silicon dioxide. In some other embodiments, the mask structure is silicon nitride while the dielectric material is silicon dioxide. In examples where the dielectric material is silicon dioxide, a thin layer of a high-k dielectric material, such as silicon nitride, may be first deposited within the gate cut recess to protect the metal gate electrode from oxidation.

Method 1800 continues with operation 1820 where the dielectric material within the gate cut recess and over the top surface of the mask structure is polished back using CMP. Various selective or nonselective polishing processes may be used depending on the material composition of the dielectric material and the mask structure, as discussed above with reference to FIGS. 9A-16A and 9B—16B. For example, if both the dielectric material and the mask structure have the same material composition (e.g., both silicon nitride or both silicon dioxide), then a single selective polishing process may be used to cut through both the dielectric material and the mask structure until a top surface of the dielectric material is substantially coplanar with a top surface of the conductive contacts and a top surface of the dielectric gate cap. In other examples where the dielectric material and the mask structure have different material compositions, more than one CMP process may be used to polish one material layer vs another and/or use nonselective CMP processes to polish through material layers having different material compositions. Regardless of which polishing method is used, the resulting gate cut has a top surface that is substantially coplanar with a top surface of the conductive contacts and a top surface of the dielectric gate cap.

### Example System

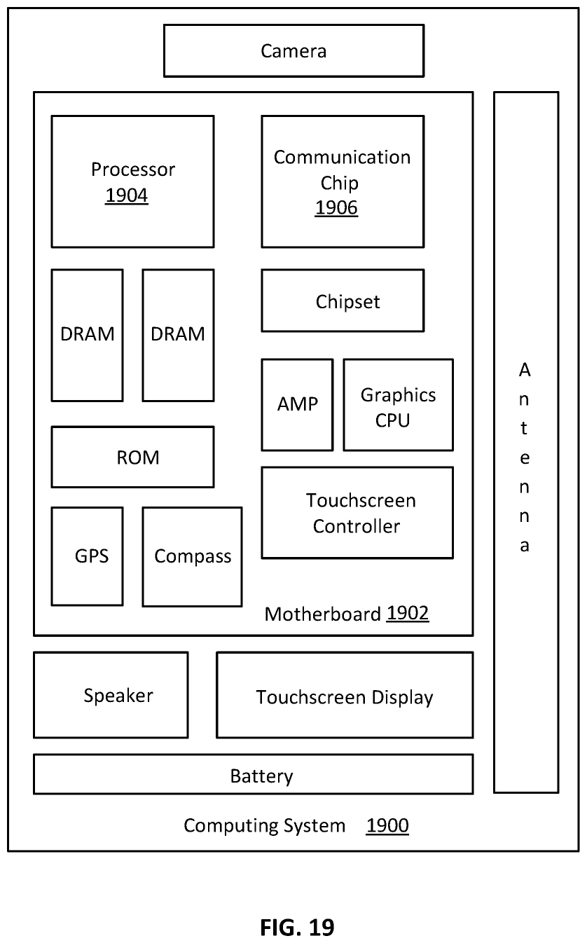

FIG. 19 is an example computing system implemented with one or more of the integrated circuit structures as disclosed herein, in accordance with some embodiments of the present disclosure. As can be seen, the computing system 1900 houses a motherboard 1902. The motherboard 1902 may include a number of components, including, but not limited to, a processor 1904 and at least one communication chip 1906, each of which can be physically and electrically coupled to the motherboard 1902, or otherwise integrated therein. As will be appreciated, the motherboard 1902 may be, for example, any printed circuit board (PCB), whether a main board, a daughterboard mounted on a main board, or the only board of system 1900, etc.

Depending on its applications, computing system 1900 may include one or more other components that may or may not be physically and electrically coupled to the motherboard 1902. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1900 may include one or more integrated circuit structures or devices configured in accordance with an example embodiment (e.g., a module including an integrated circuit on a substrate, the substrate having semiconductor devices and at least one gate cut with a top surface substantially coplanar with a top surface of the conductive source/drain contacts). In some embodiments, multiple functions can be integrated into one or more chips (e.g., for instance, note that the communication chip 1906 can be part of or otherwise integrated into the processor 1904).

The communication chip 1906 enables wireless communications for the transfer of data to and from the computing system 1900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1906 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1900 may include a plurality of communication chips 1906. For instance, a first communication chip 1906 may be dedicated to shorter range wireless communications such as Wi-Fi and Bluetooth and a second communication chip 1906 may be dedicated to longer range wireless communications such as GPS, EDGE, GPRS, CDMA, WiMAX, LTE, Ev-DO, and others.

The processor 1904 of the computing system 1900 includes an integrated circuit die packaged within the processor 1904. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1906 also may include an integrated circuit die packaged within the communication chip 1906. In accordance with some such example embodiments, the integrated circuit die of the communication chip includes one or more semiconductor devices as variously described herein. As will be appreciated in light of this disclosure, note that multi-standard wireless capability may be integrated directly into the processor 1904 (e.g., where functionality of any chips 1906 is integrated into processor 1904, rather than having separate communication chips). Further note that processor 1904 may be a chip set having such wireless capability. In short, any number of processor 1904 and/or communication chips 1906 can be used. Likewise, any one chip or chip set can have multiple functions integrated therein.

In various implementations, the computing system 1900 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1900 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction between a source region and a drain region, and a gate structure extending in a second direction over the semiconductor region, a dielectric layer on a top surface of the gate structure, a first conductive contact on the source region and a second conductive contact on the drain region, and a gate cut extending in a third direction through an entire thickness of the gate structure. The gate cut includes a dielectric material and a top surface of the gate cut is substantially coplanar with a top surface of the dielectric layer and top surfaces of the first and second conductive contacts. In one such example, the height variation between two surfaces that are substantially coplanar may be less than 1 nm. In another such example, two surfaces are considered to be substantially coplanar if they are polished together using the same chemical mechanical polishing (CMP) process.

Example 2 includes the integrated circuit of Example 1, wherein the dielectric material comprises silicon and nitrogen.

Example 3 includes the integrated circuit of Example 1, wherein the dielectric material comprises silicon and oxygen.

Example 4 includes the integrated circuit of any one of Examples 1-3, wherein the gate cut contacts at least a portion of the source region and/or the drain region.

Example 5 includes the integrated circuit of any one of Examples 1-4, wherein the dielectric layer comprises silicon and nitrogen.

Example 6 includes the integrated circuit of any one of Examples 1-5, wherein the gate cut comprises a dielectric liner and a dielectric fill on the dielectric liner, wherein the dielectric liner has a higher dielectric constant than the dielectric fill.

Example 7 includes the integrated circuit of any one of Examples 1-6, wherein the dielectric layer has a thickness between about 10 nm and about 20 nm.

Example 8 includes the integrated circuit of any one of Examples 1-7, wherein the semiconductor region comprises a plurality of semiconductor nanoribbons.

Example 9 includes the integrated circuit of Example 8, wherein the plurality of semiconductor nanoribbons comprise germanium, silicon, or a combination thereof.

Example 10 includes the integrated circuit of any one of Examples 1-9, wherein the gate structure includes a gate dielectric around the semiconductor region.

Example 11 includes the integrated circuit of Example 10, wherein the gate dielectric is not present on any sidewall of the gate cut.

Example 12 is a printed circuit board that includes the integrated circuit of any one of Examples 1-11.

Example 13 is an electronic device that includes a chip package comprising one or more dies. At least one of the one or more dies includes a semiconductor device having a semiconductor region extending in a first direction between a source region and a drain region, and a gate structure extending in a second direction over the semiconductor region, a dielectric layer on a top surface of the gate structure, a first conductive contact on the source region and a second conductive contact on the drain region, and a gate cut extending in a third direction through an entire thickness of the gate structure. The gate cut includes a dielectric material and a top surface of the gate cut is substantially coplanar with a top surface of the dielectric layer and a top surface of the first and/or second conductive contact. In one such example, the height variation between two surfaces that are substantially coplanar may be less than 1 nm. In another such example, two surfaces are considered to be substantially coplanar if they are polished together using the same chemical mechanical polishing (CMP) process.

Example 14 includes the electronic device of Example 13, wherein the dielectric material comprises silicon and nitrogen.

Example 15 includes the electronic device of Example 13, wherein the dielectric material comprises silicon and oxygen.

Example 16 includes the integrated circuit of any one of Examples 13-15, wherein the gate cut contacts at least a portion of the source region and/or the drain region.

Example 17 includes the integrated circuit of any one of Examples 13-16, wherein the dielectric layer comprises silicon and nitrogen.

Example 18 includes the integrated circuit of any one of Examples 13-17, wherein the gate cut comprises a dielectric liner and a dielectric fill on the dielectric liner, wherein the dielectric liner has a higher dielectric constant than the dielectric fill.

Example 19 includes the integrated circuit of any one of Examples 13-18, wherein the dielectric layer has a thickness between about 10 nm and about 20 nm.

Example 20 includes the integrated circuit of any one of Examples 13-19, wherein the semiconductor region comprises a plurality of semiconductor nanoribbons.

Example 21 includes the electronic device of Example 20, wherein the plurality of semiconductor nanoribbons comprise germanium, silicon, or a combination thereof.

Example 22 includes the integrated circuit of any one of Examples 13-21, wherein the gate structure includes a gate dielectric around the semiconductor region.

Example 23 includes the electronic device of Example 22, wherein the gate dielectric is not present on any sidewall of the gate cut.

Example 24 includes the integrated circuit of any one of Examples 13-23, further comprising a printed circuit board, wherein the chip package is coupled to the printed circuit board.

Example 25 is a method of forming an integrated circuit. The method includes forming a fin comprising semiconductor material, the fin extending above a substrate and extending in a first direction; forming a source region and a drain region at opposite ends of the semiconductor material; forming a gate structure extending over the semiconductor material in a second direction different from the first direction; forming a dielectric layer on a top surface of the gate structure; forming a first conductive contact on the source region and a second conductive contact on the drain region; forming a dielectric mask layer over the dielectric layer and over the first conductive contact and second conductive contact; forming a recess through the dielectric mask layer and through an entire thickness of the gate electrode; depositing a dielectric material within the recess and over at least a top surface of the dielectric mask layer; and recessing the dielectric material using chemical mechanical polishing (CMP).

Example 26 includes the method of Example 25, wherein the dielectric mask layer and the dielectric material comprise the same dielectric material, and wherein recessing the dielectric material comprises recessing the dielectric material using CMP until a top surface of the dielectric material is substantially coplanar with a top surface of the dielectric layer and top surfaces of the first and second conductive contacts. In one such example, the height variation between two surfaces that are substantially coplanar may be less than 1 nm, because they are polished together.

Example 27 includes the method of Example 26, wherein the dielectric mask layer and the dielectric material both comprise silicon and nitrogen.

Example 28 includes the method of Example 26, wherein the dielectric mask layer and the dielectric material both comprise silicon and oxygen.

Example 29 includes the method of Example 25, wherein the dielectric mask layer and the dielectric material comprise different dielectric materials, and wherein recessing the dielectric material comprises recessing the dielectric material using CMP until a top surface of the dielectric material is substantially coplanar with a top surface of the dielectric layer and a top surface of the first conductive contact and/or a top surface of the second conductive contact. In one such example, the height variation between two surfaces that are substantially coplanar may be less than 1 nm, because they are polished together.

Example 30 includes the method of Example 29, wherein the dielectric mask layer comprises silicon and nitrogen and the dielectric material comprises silicon and oxygen.

Example 31 includes the method of any one of Examples 25-30, wherein recessing the dielectric material comprises recessing the dielectric material using CMP until a top surface of the of the dielectric material is substantially coplanar with a top surface of the dielectric mask layer. In one such example, the height variation between two surfaces that are substantially coplanar may be less than 1 nm, because they are polished together.

Example 32 includes the method of Example 31, further comprising recessing both the dielectric material and the dielectric mask layer using a nonselective CMP process until a top surface of the dielectric material is substantially coplanar with a top surface of the dielectric layer and a top surface of the first conductive contact and/or a top surface of the second conductive contact.

Example 33 includes the method of Example 31 or 32, further comprising recessing the dielectric material until a top surface of the dielectric material is coplanar with or below a top surface of the dielectric layer, the recessing forming a second recess through the dielectric mask layer; forming a dielectric fill having a same material composition as the dielectric mask layer within the second recess; and recessing both the dielectric mask layer and the dielectric fill using CMP until a top surface of the dielectric material is exposed.

Example 34 includes the method of any one of Examples 31-33, wherein the dielectric fill and the dielectric mask layer comprises silicon and nitrogen, and the dielectric material comprises silicon and oxygen.

Example 35 is an integrated circuit that includes a semiconductor region extending in a first direction between a first source or drain region and a second source or drain region, a gate structure extending in a second direction over the semiconductor region, a dielectric layer on a top surface of the gate structure, a first conductive contact on the first source or drain region and a second conductive contact on the second source or drain region, and a gate cut extending in a third direction through an entire thickness of the gate structure and extending in the first direction such that the gate cut contacts at least a portion of the first source or drain region and at least a portion of the first conductive contact. The gate cut includes a dielectric material and has a top surface that is substantially coplanar with a top surface of the dielectric layer and a top surface of the first conductive contact. In one such example, the height variation between two surfaces that are substantially coplanar may be less than 1 nm. In another such example, two surfaces are considered to be substantially coplanar if they are polished together using the same chemical mechanical polishing (CMP) process.

Example 36 includes the integrated circuit of Example 35, wherein the dielectric material comprises silicon and nitrogen.

Example 37 includes the integrated circuit of Example 35, wherein the dielectric material comprises silicon and oxygen.

Example 38 includes the integrated circuit of any one of Examples 35-37, wherein the dielectric layer comprises silicon and nitrogen.

Example 39 includes the integrated circuit of any one of Examples 35-38, wherein the gate cut comprises a dielectric liner and a dielectric fill on the dielectric liner, wherein the dielectric liner has a higher dielectric constant than the dielectric fill.

Example 40 includes the integrated circuit of any one of Examples 35-39, wherein the dielectric layer has a thickness between about 10 nm and about 20 nm.

Example 41 includes the integrated circuit of any one of Examples 35-40, wherein the gate structure includes a gate dielectric around the semiconductor region.

Example 42 includes the integrated circuit of Example 41, wherein the gate dielectric is not present on any sidewall of the gate cut.

Example 43 is a printed circuit board comprising the integrated circuit of any one of Examples 35-42.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction between a source region and a drain region, and a gate structure extending in a second direction over the semiconductor region;
a dielectric layer on a top surface of the gate structure;
a first conductive contact on the source region and a second conductive contact on the drain region; and
a gate cut extending in a third direction through an entire thickness of the gate structure, wherein the gate cut comprises a dielectric material and wherein a top surface of the gate cut is substantially coplanar with a top surface of the dielectric layer and top surfaces of the first and second conductive contacts.

2. The integrated circuit of claim 1, wherein the dielectric material comprises silicon and nitrogen or comprises silicon and oxygen.

3. The integrated circuit of claim 1, wherein the gate cut contacts at least a portion of the source region and/or the drain region.

4. The integrated circuit of claim 1, wherein the dielectric layer comprises silicon and nitrogen.

5. The integrated circuit of claim 1, wherein the gate cut comprises a dielectric liner and a dielectric fill on the dielectric liner, wherein the dielectric liner has a higher dielectric constant than the dielectric fill.

6. The integrated circuit of claim 1, wherein the semiconductor region comprises a plurality of semiconductor nanoribbons.

7. The integrated circuit of claim 1, wherein the gate structure includes a gate dielectric around the semiconductor region and the gate dielectric is not present on any sidewall of the gate cut.

8. A printed circuit board comprising the integrated circuit of claim 1.

9. An electronic device, comprising:
a chip package comprising one or more dies, at least one of the one or more dies comprising
a semiconductor device having a semiconductor region extending in a first direction between a source region and a drain region, and a gate structure extending in a second direction over the semiconductor region;
a dielectric layer on a top surface of the gate structure;
a first conductive contact on the source region and a second conductive contact on the drain region; and
a gate cut extending in a third direction through an entire thickness of the gate structure, wherein the gate cut comprises a dielectric material and wherein a top surface of the gate cut is substantially coplanar with a top surface of the dielectric layer and a top surface of the first and/or second conductive contact.

10. The electronic device of claim 9, wherein the dielectric material comprises silicon and nitrogen or comprises silicon and oxygen.

11. The electronic device of claim 9, wherein the gate cut contacts at least a portion of the source region and/or the drain region.

12. The electronic device of claim 9, wherein the gate cut comprises a dielectric liner and a dielectric fill on the dielectric liner, wherein the dielectric liner has a higher dielectric constant than the dielectric fill.

13. The electronic device of claim 9, wherein the gate structure includes a gate dielectric around the semiconductor region.

14. The electronic device of claim 13, wherein the gate dielectric is not present on any sidewall of the gate cut.

15. The electronic device of claim 9, further comprising a printed circuit board, wherein the chip package is coupled to the printed circuit board.

16. An integrated circuit comprising:
a semiconductor region extending in a first direction between a first source or drain region and a second source or drain region;
a gate structure extending in a second direction over the semiconductor region;
a dielectric layer on a top surface of the gate structure;
a first conductive contact on the first source or drain region and a second conductive contact on the second source or drain region; and
a gate cut extending in a third direction through an entire thickness of the gate structure and extending in the first direction such that the gate cut contacts at least a portion of the first source or drain region and at least a portion of the first conductive contact, the gate cut comprising a dielectric material and having a top surface that is substantially coplanar with a top surface of the dielectric layer and a top surface of the first conductive contact.

17. The integrated circuit of claim 16, wherein the dielectric material comprises silicon and nitrogen or comprises silicon and oxygen.

18. The integrated circuit of claim 16, wherein the dielectric layer comprises silicon and nitrogen.

19. The integrated circuit of claim 16, wherein the gate cut comprises a dielectric liner and a dielectric fill on the dielectric liner, wherein the dielectric liner has a higher dielectric constant than the dielectric fill.

20. The integrated circuit of claim 16, wherein the gate structure includes a gate dielectric around the semiconductor region and the gate dielectric is not present on any sidewall of the gate cut.
